(19) United States
(12) Patent Application Publication
(10) Pub. No.: US 2026/0299796 A1
(43) Pub. Date: Oct. 1, 2026

(54) MEMORY DEVICE, OPERATING METHOD THEREOF AND MEMORY SYSTEM

(71) Applicant: YANGTZE MEMORY TECHNOLOGIES CO., LTD., Wuhan (CN)

(72) Inventors: Xingwei TANG, Wuhan (CN); Guangchang YE, Wuhan (CN); Lu GUO, Wuhan (CN); Weijun WAN, Wuhan (CN); Yahai LIU, Wuhan (CN)

(21) Appl. No.: 19/289,787

(22) Filed: Aug. 4, 2025

(30) Foreign Application Priority Data
Mar. 31, 2025 (CN) 2025103940873

(51) Int. Cl. G06F 3/06; G11C 16/04; G11C 16/26

(52) U.S. Cl. CPC G06F 3/0619; G06F 3/0659; G06F 3/0679; G11C 16/0483; G11C 16/26

(57) ABSTRACT

A memory device includes: a memory cell array comprising memory cells, wherein a preset number of the memory cells form a codeword; and a peripheral circuit coupled to the memory cell array and configured to: receive a read retry command for instructing to obtain target data stored in a target codeword; obtain a valley bottom voltage in response to the read retry command, wherein the valley bottom voltage is used as a read voltage when performing a read operation on the target codeword; and perform the read operation on the target codeword based on the valley bottom voltage to obtain the target data.

### CROSS-REFERENCE TO RELATED APPLICATIONS

The present disclosure claims priority to Chinese Patent Application No. 2025103940873, which was filed Mar. 31, 2025, and is hereby incorporated herein by reference in its entirety.

### TECHNICAL FIELD

Examples of the present disclosure relate to the field of semiconductor technologies, including but not limited to a memory device, an operating method thereof, and a memory system.

### BACKGROUND

With the development of science and technology, the market scale of the integrated circuit industry is getting larger and larger, and in the whole integrated circuit industry, the process and technology of non-volatile memory devices have been developed in recent years, wherein NAND-type memory devices are especially widely used. NAND-type memory devices enable the function of data storage by trapping and storing charges in the gate dielectric layer of memory cells contained therein. However, with the increase of the usage time, the charges stored in the memory cells will vary with the increase of the usage time, repeated read operations, cross temperatures, etc., which will affect the correctness of reading the data stored in the memory cells.

### SUMMARY

Examples of the present disclosure provide a memory device, an operating method thereof, and a memory system.

In a first aspect, an example of the present disclosure provides a memory device, comprising: a memory cell array comprising a plurality of memory cells, wherein a preset number of memory cells among the plurality of memory cells form a codeword; and a peripheral circuit coupled to the memory cell array and configured to: receive a read retry command for instructing to obtain target data stored in a target codeword; obtain a valley bottom voltage in response to the read retry command, wherein the valley bottom voltage is used as a read voltage when performing a read operation on the target codeword; and perform the read operation on the target codeword based on the valley bottom voltage to obtain the target data.

In some examples, the peripheral circuit comprises: a register configured to: store a mapping table; and control logic coupled to the register and configured to: receive the read retry command; obtain the valley bottom voltage based on the target codeword and the mapping table; and perform the read operation on the target codeword based on the valley bottom voltage to obtain the target data.

In some examples, the memory cell array comprises: a configuration block configured to: store the mapping table, and wherein the control logic is configured to: store the mapping table in the configuration block into the register when the memory device undergoes Power On Reset (POR).

In some examples, the peripheral circuit further comprises: a latch coupled to the control logic, and wherein the control logic is configured to: store the target data into the latch.

In some examples, the number of bits stored in each of the memory cells is M, the stored M bits correspond to 2^{M}−1 read levels comprising a reference read level, and M is an integer greater than or equal to 2, and wherein the control logic is configured to: obtain a first result corresponding to a reference codeword at a reference read voltage of the reference read level as a characteristic value, wherein the first result is to indicate the number of bits flipped between two read results of the reference codeword at a first read voltage and a second read voltage, and a difference value between the first read voltage and the second read voltage is less than a preset voltage; and obtain a characteristic level corresponding to the characteristic value based on the characteristic value, wherein the characteristic level is to indicate one or more continuously arranged characteristic values.

In some examples, the control logic is configured to: determine a word line group corresponding to the target codeword based on a position of the target codeword in the memory cell array, wherein the word line group is to indicate one or more word lines disposed adjacently.

In some examples, the control logic is configured to: determine at least one offset prediction based on the characteristic level, a target read level of the target codeword, and the word line group corresponding to the target codeword in combination with the mapping table, wherein the mapping table comprises a mapping relationship among the characteristic level, the target read level, the word line group, and the offset prediction; and obtain the valley bottom voltage based on the at least one offset prediction.

In some examples, the at least one offset prediction comprises two offset predictions, and two preset first results corresponding to the two preset offsets are both within a preset interval, and wherein the control logic is configured to: determine two target read voltages based on the two offset predictions; obtain a first result corresponding to the target codeword at one of the target read voltages, and obtain a first result corresponding to the target codeword at the other one of the target read voltages; and obtain the valley bottom voltage based on the two target read voltages and two corresponding first results in combination with a preset function model.

In some examples, the preset function model comprises a quadratic function model comprising following function relation: y=a(x+b)²+c, wherein y represents the first result, x represents the target read voltage, b represents a prediction parameter, a represents a first parameter, and c represents a second parameter.

In some examples, the first parameter is a variable and the second parameter is a constant, and wherein the control logic is configured to: obtain the prediction parameter based on the two target read voltages and the two corresponding first results in combination with the quadratic function model; and use the prediction parameter as the valley bottom voltage.

In some examples, the control logic is configured to: read data stored in the reference codeword at the first read voltage to obtain a second result; read data stored in the reference codeword at the second read voltage to obtain a third result; perform a logical operation on the second result and the third result to obtain a fourth result; and count the number of bits in the fourth result indicating that the third result is flipped relative to the second result, to obtain the first result.

In a second aspect, an example of the present disclosure provides a memory system, comprising: at least one memory device according to the above technical solutions; and a controller coupled to the memory device and configured to control the memory device.

In some examples, the controller is configured to send a read retry command, the memory device is configured to receive the read retry command to obtain target data, and the controller is further configured to obtain the target data.

In a third aspect, an example of the present disclosure provides an operating method of a memory device, wherein the memory device comprises: a memory cell array comprising a plurality of memory cells, wherein a preset number of memory cells among the plurality of memory cells form a codeword; and a peripheral circuit coupled to the memory cell array, and wherein the operating method comprises: receiving a read retry command for instructing to obtain target data stored in a target codeword; obtaining a valley bottom voltage in response to the read retry command, wherein the valley bottom voltage is used as a read voltage when performing a read operation on the target codeword; and performing the read operation on the target codeword based on the valley bottom voltage to obtain the target data.

In some examples, the peripheral circuit comprises: a register configured to: store a mapping table, and wherein obtaining the valley bottom voltage in response to the read retry command comprises: obtaining the valley bottom voltage based on the target codeword and the mapping table.

In some examples, the memory cell array comprises: a configuration block configured to: store the mapping table, and wherein the operating method further comprises: storing the mapping table in the configuration block into the register when the memory device undergoes Power On Reset (POR).

In some examples, the number of bits stored in each of the memory cells is M, the stored M bits correspond to 2^{M}−1 read levels comprising a reference read level, and M is an integer greater than or equal to 2, and wherein obtaining the valley bottom voltage based on the target codeword and the mapping table comprises: obtaining a first result corresponding to a reference codeword at a reference read voltage of the reference read level as a characteristic value, wherein the first result is to indicate the number of bits flipped between two read results of the reference codeword at a first read voltage and a second read voltage, and a difference value between the first read voltage and the second read voltage is less than a preset voltage; and obtaining a characteristic level corresponding to the characteristic value based on the characteristic value, wherein the characteristic level is to indicate one or more continuously arranged characteristic values.

In some examples, obtaining the valley bottom voltage based on the target codeword and the mapping table further comprises: determining a word line group corresponding to the target codeword based on a position of the target codeword in the memory cell array, wherein the word line group is to indicate one or more word lines disposed adjacently.

In some examples, obtaining the valley bottom voltage based on the target codeword and the mapping table further comprises: determining at least one offset prediction based on the characteristic level, a target read level of the target codeword, and the word line group corresponding to the target codeword in combination with the mapping table, wherein the mapping table comprises a mapping relationship among the characteristic level, the target read level, the word line group, and the offset prediction; and obtaining the valley bottom voltage based on the at least one offset prediction.

In some examples, the at least one offset prediction comprises two offset predictions, and two preset first results corresponding to the two preset offsets are both within a preset interval, and wherein obtaining the valley bottom voltage based on the at least one offset prediction comprises: determining two target read voltages based on the two offset predictions; obtaining a first result corresponding to the target codeword at one of the target read voltages, and obtaining a first result corresponding to the target codeword at the other one of the target read voltages; and obtaining the valley bottom voltage based on the two target read voltages and two corresponding first results in combination with a preset function model.

In some examples, the preset function model comprises a quadratic function model comprising following function relation: y=a(x+b)²+c, wherein y represents the first result, x represents the target read voltage, b represents a prediction parameter, a represents a first parameter, and c represents a second parameter.

In some examples, obtaining the valley bottom voltage based on the two target read voltages and the two corresponding first results in combination with the preset function model comprises: obtaining the prediction parameter based on the two target read voltages and the two corresponding first results in combination with the quadratic function model; and using the prediction parameter as the valley bottom voltage.

In some examples, obtaining the first result corresponding to the reference codeword at the reference read voltage of the reference read level comprises: reading data stored in the reference codeword at the first read voltage to obtain a second result; reading data stored in the reference codeword at the second read voltage to obtain a third result; performing a logical operation on the second result and the third result to obtain a fourth result; and counting the number of bits in the fourth result indicating that the third result is flipped relative to the second result, to obtain the first result.

Examples of present disclosure provide a memory device, an operating method thereof, and a memory system. The peripheral circuit in the memory device is configured to: receive a read retry command; obtain a valley bottom voltage in response to the read retry command; and perform a read operation on the target codeword based on the valley bottom voltage to obtain the target data. As such, the process of finding the valley bottom voltage is done entirely autonomously by the memory device without relying on any input or determination provided by the controller.

### BRIEF DESCRIPTION OF THE DRAWINGS

In the drawings, same reference numbers refer to the same or similar components or elements throughout the several drawings unless otherwise specified. These figures are not necessarily drawn to scale. It should be understood that these figures depict only some examples according to the present disclosure and should not be considered as limiting the scope of the present disclosure.

FIG. 1 is a block diagram of an electronic device with a memory device according to an example of the present disclosure;

FIG. 2 is a schematic diagram of a memory card having a memory device according to an example of the present disclosure;

FIG. 3 is a schematic diagram of a solid state drive with a memory device according to an example of the present disclosure;

FIG. 4 is a schematic diagram of a memory device including a peripheral circuit according to an example of the present disclosure;

FIG. 5 is a schematic cross-sectional view of a memory cell array including a memory string according to an example of the present disclosure;

FIG. 6 is a block diagram of a memory device including a peripheral circuit according to an example of the present disclosure;

FIG. 7 is a schematic diagram of a process of an operating method that a memory device configured to perform according to an example of the present disclosure;

FIG. 8 is a threshold voltage distribution diagram corresponding to memory cells that store two bits according to an example of the present disclosure;

FIG. 9 is a threshold voltage distribution diagram corresponding to memory cells that store three bits according to an example of the present disclosure;

FIG. 10 is a threshold voltage distribution diagram corresponding to memory cells that store four bits according to an example of the present disclosure;

FIG. 11 is a threshold voltage distribution diagram corresponding to memory cells when obtaining a first result according to an example of the present disclosure;

FIG. 12 is a schematic diagram of determining a characteristic level according to an example;

FIG. 13 is a schematic diagram of a mapping table according to an example of the present disclosure;

FIG. 14 is a schematic flowchart of determining a valley bottom voltage according to some examples of the present disclosure;

FIG. 15 is a schematic diagram of a preset function model according to some examples of the present disclosure; and

FIG. 16 is a schematic diagram of determining a predicted valley bottom voltage based on a preset function model according to some examples of the present disclosure.

### DETAILED DESCRIPTION

The technical solutions in the examples of the present disclosure will be clearly and completely described below with reference to the examples of the present disclosure and the accompanying figures, and obviously, the described examples are only a part of the examples of the present disclosure, but not all the examples. Based on the examples in the present disclosure, all other examples obtained by those skilled in the art without creative efforts fall within the protection scope of the present disclosure.

In the following description, numerous specific details are given in order to provide a more thorough understanding of the present disclosure. It will be apparent, however, to one skilled in the art that the present disclosure may be practiced without one or more of these details. In other examples, some technical features well-known in the art are not described to avoid confusion with the present disclosure; for example, not all features of the actual example are described here, and well-known functions and structures are not described in detail.

In the drawings, the size of layers, regions, elements and their relative sizes may be exaggerated for clarity. Like reference numerals refer to like elements throughout.

It will be understood that when an element or layer is referred to as being “on,” “adjacent to,” “connected to” or “coupled to” other elements or layers, it can be directly on, adjacent to, connected to, or coupled to other elements or layers, or intervening elements or layers may be present. In contrast, when an element is referred to as being “directly on,” “directly adjacent to,” “directly connected to” or “directly coupled to” other elements or layers, there are no intervening elements or layers. It will be understood that, although the terms such as first, second, third etc. may be used to describe at least one of various elements, components, regions, layers or sections, at least one of these elements, components, regions, layers or sections should not be limited by these terms. These terms are only used to distinguish one element, component, region, layer or section from another element, component, region, layer or section. Thus, a first element, component, region, layer or section discussed below could be represented as a second element, component, region, layer or section without departing from the teachings of the present disclosure. When a second element, component, region, layer or section is discussed, it does not indicate that a first element, component, region, layer or section exists in the present disclosure.

Spatial relationship terms such as “under”, “below”, “beneath”, “underneath”, “on”, “above” and so on, can be used here for convenience to describe the relationship between one element or feature and other elements or features shown in the figures. It will be understood that the spatially relationship terms also comprise different orientations of the device in use and operation in addition to the orientation depicted in the figures. For example, if the device in the figures is turned over, elements or features described as “below” or “underneath” or “under” other elements or features would then be oriented as “above” the other elements or features. Thus, the example terms “below” and “under” can comprise both orientations of above and below. The device may be otherwise oriented (rotated 90 degrees or at other orientations) and the spatial descriptors used herein may be interpreted accordingly.

The terminology used herein is for the purpose of describing particular examples only and is not to be taken as a limitation of the present disclosure. As used herein, “a”, “an” and “said/the” in singular forms are intended to include the plural forms as well, unless the context clearly dictates otherwise. It should also be understood that at least one of the terms “consists of” or “comprising”, when used in this specification, identify the presence of at least one of stated features, integers, operations, elements or components, but do not exclude presence or addition of at least one of one or more other features, integers, operations, elements, components or groups. As used herein, the term “at least one of . . . ” includes any and all combinations of the associated listed items.

For a thorough understanding of the present disclosure, detailed operations and detailed structures will be provided in the following description to explain the technical solutions of the present disclosure. Examples of the present disclosure are described in detail below, however, in addition to these detailed descriptions, the present disclosure may have other examples.

The memory device in the examples of the present disclosure may include but is not limited to a three-dimensional NAND-type memory device, and for ease of understanding, a three-dimensional NAND-type memory device is used as an example for illustration.

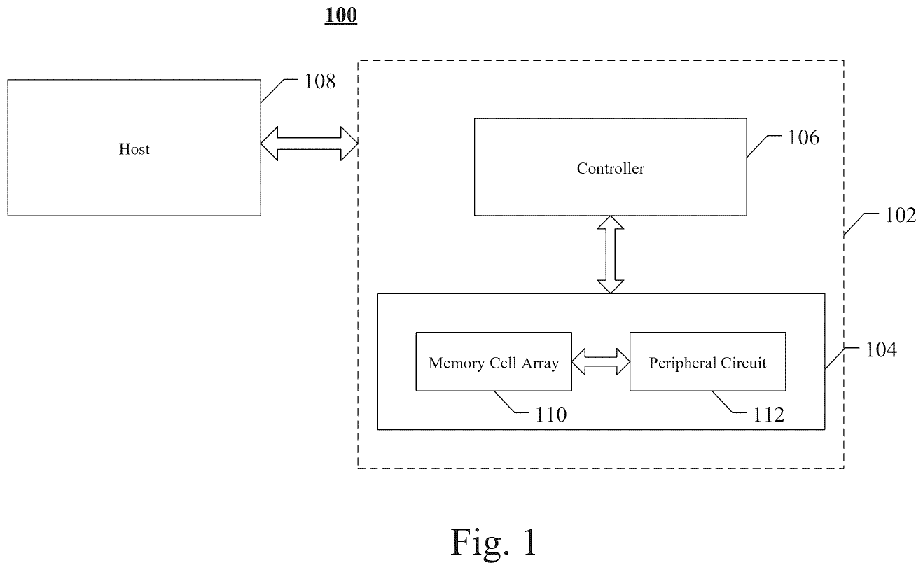

Referring to FIG. 1, FIG. 1 is a block diagram of an electronic device with a memory device according to an example of the present disclosure. As shown in FIG. 1, the electronic device 100 may comprise a mobile phone, a desktop computer, a laptop computer, a tablet computer, a vehicle computer, a game console, a printer, a positioning device, a wearable electronic device, an intelligent sensor, a virtual reality (VR) device, an augmented reality (AR) device, or any other suitable electronic device with a memory device therein.

As shown in FIG. 1, the electronic device 100 may include a host 108 and a memory system 102 (as shown by a dashed box in FIG. 1), the memory system 102 has one or more memory devices 104 and a controller 106, and only one memory device 104 is illustrated for example description in FIG. 1. The host 108 may include a processor (e.g., a central processing unit (CPU)) or a system on chip (SoC) (e.g., an application processor (AP)) of the electronic device. The host 108 may be configured to send data to or receive data from the memory device 104.

In some examples, the controller 106 is coupled to the memory device 104 and the host 108 and is configured to the control memory device 104. The controller 106 may manage data stored in the memory device 104 and communicate with the host 108.

In some examples, the controller 106 is designed for operating in a low duty cycle environment such as a Secure Digital (SD) card, a Compact Flash (CF) card, a Universal Serial Bus (USB) flash drive, or other medium for use in electronic devices such as personal calculators, digital cameras, mobile phones, etc.

In some examples, the controller 106 is designed for operating in a high duty cycle environment such as Solid State Drive (SSD) or embedded Multi-Media Card (eMMC), which is used as a data storage for mobile devices such as smartphones, tablets, laptops, and the like, and an enterprise storage array.

The controller 106 may be configured to control operations of the memory device 104, such as read, erase, and program operations. The controller 106 may also be configured to manage various functions regarding data stored or to be stored in the memory device 104, including but not limited to bad block management, garbage collection, logical address to physical address translation, wear leveling, and the like. In some examples, the controller 106 is further configured to process error correcting codes (ECC) regarding data read from or written to the memory device 104.

The controller 106 may also perform any other suitable function, such as formatting the memory device 104. Controller 106 may communicate with external devices (e.g., host 108) according to a particular communication protocol. For example, the controller 106 may communicate with an external device through at least one of various interface protocols, such as USB protocol, MMC protocol, Peripheral Component Interconnect (PCI) protocol, PCI Express (PCI-E) protocol, Advanced Technology Attachment (ATA) protocol, Serial ATA protocol, Parallel ATA protocol, Small Computer System Interface (SCSI) protocol, Enhanced Small Drive Interface (ESDI) protocol, Integrated Drive Electronics (IDE) protocol, Firewire protocol, or the like.

The controller 106 and the one or more memory devices 104 may be integrated into various types of storage devices, for example, included in the same package (e.g., Universal Flash Storage (UFS) package or eMMC package). For example, the memory system 102 may be implemented and packaged into different types of terminal electronics.

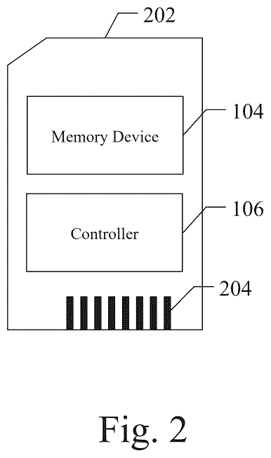

Referring to FIG. 2, FIG. 2 is a schematic diagram of a memory card with a memory device according to an example of the present disclosure. As shown in FIG. 2, a controller 106 and single memory device 104 may be integrated into the memory card 202. The memory card 202 may include a Personal Computer Memory Card International Association (PCMCIA) card, a CF card, a Smart Media (SM) card, a memory stick, a multimedia card (e.g., MMC, Reduced Size MMC (RS-MMC), microMMC), an SD (e.g., SD, miniSD, microSD, Secure Digital High Capacity (SDHC)) card, a UFS, etc. The memory card 202 may also include a memory card connector 204 that couples the memory card 202 and a host (e.g., host 108 in FIG. 1).

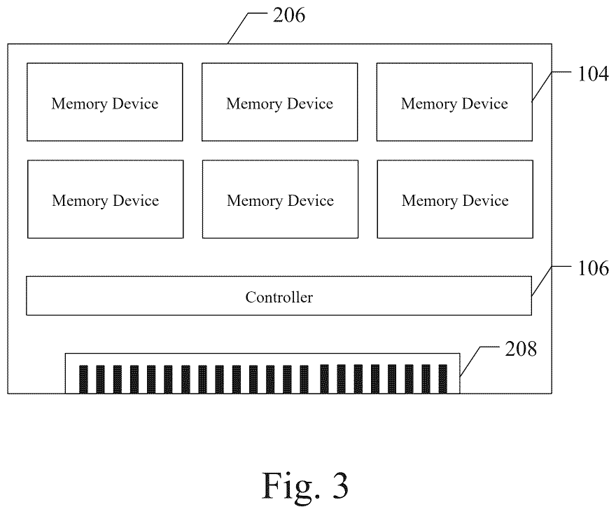

Referring to FIG. 3, FIG. 3 is a schematic diagram of a solid state drive with a memory device according to an example of the present disclosure. As shown in FIG. 3, the controller 106 and a plurality of memory devices 104 may be integrated into the solid state drive 206. The solid state drive 206 may also include a solid state drive connector 208 that couples the solid state drive 206 and a host (e.g., host 108 in FIG. 1). In some examples, at least one of the storage capacity or operating speed of the solid state drive 206 is greater than that of the memory card 202.

Referring back to FIG. 1, the memory device 104 further includes a memory cell array 110 and a peripheral circuit 112 coupled to the memory cell array 110. The memory cell array 110 may comprise a NAND flash memory cell array.

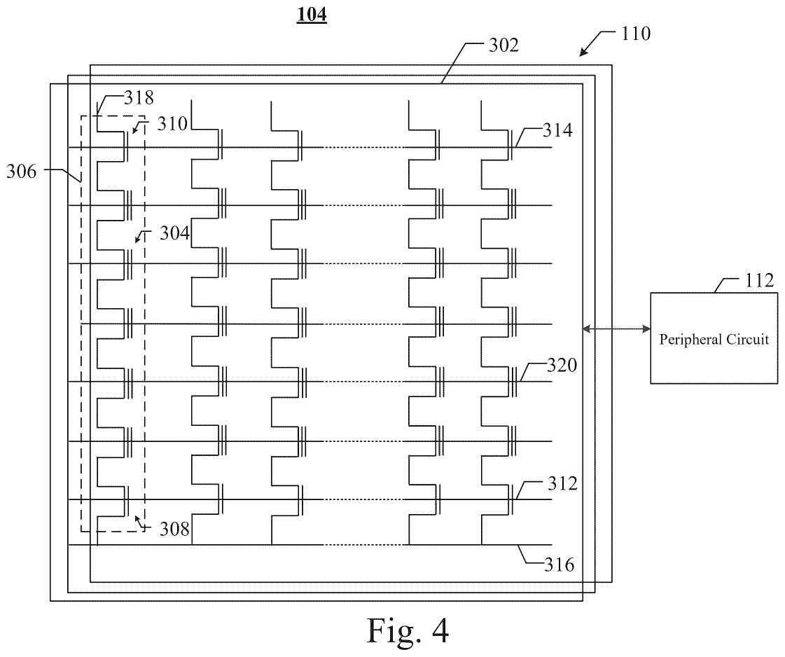

Referring to FIG. 4, FIG. 4 is a schematic diagram of a memory device including a peripheral circuit according to an example of the present disclosure. The memory device 104 may include a memory cell array 110 and a peripheral circuit 112 coupled to the memory cell array 110. The memory cells 304 are provided in the form of an array of memory strings 306, each of which extends vertically above a substrate (not illustrated in FIG. 4) as illustrated by the dashed box in FIG. 4. In some examples, each memory string 306 includes a plurality of memory cells 304 coupled in series and stacked vertically. Each memory cell 304 may hold a continuous analog value, e.g., voltage or charge, that depends on the number of electrons trapped within the region of the memory cell 304. Each memory cell 304 may be a floating gate type memory cell including a floating gate transistor or a charge trapping type memory cell including a charge trapping transistor.

In some examples, each memory cell 304 may be a single-level cell (SLC) that has two possible memory states and thus may store one bit of data. For example, the SLC may include a state 0 and a state 1, wherein the threshold voltage distribution of the state 0 may correspond to a first voltage range and the threshold voltage distribution of the state 1 may correspond to a second voltage range. The state 0 is an erased state, and the state 1 is a programmed state. In some examples, each memory cell 304 is a multi-level cell (MLC) that is capable of storing more than a single bit of data in more than four memory states. For example, an MLC may store two bits of data per cell, three bits of data per cell (also referred to as a triple-level cell (TLC)), or four bits of data per cell (also referred to as a quad-level cell (QLC)). Each MLC may be programmed to adopt a voltage range of possible threshold voltage distributions. In one example, if each MLC stores two bits of data, the MLC may have a state 0 “11”, a state 1 “10”, a state 2 “00”, and a state 3 “01”, wherein the threshold voltage distributions of the state 0, the state 1, the state 2, and the state 3 correspond to the first, second, third, and fourth voltage ranges, respectively. The state 0 is an erased state, and the state 1, the state 2, and the state 3 are all programmed states. Similarly. A TLC may include an erased state and 7 programmed states; and a QLC may include an erased state and 15 programmed states.

As shown in FIG. 4, each memory string 306 may include a source selective transistor (SST) 308 at its source terminal and a drain selective transistor (DST) 310 at its drain terminal. The source selective transistor 308 and the drain selective transistor 310 may be configured to activate a selected memory string 306 (a column of the array) during read and program operations. In some examples, the sources of the memory strings 306 in a same memory block 302 are coupled by a same source line 316 (e.g., a common SL). In other words, in some examples, all memory strings 306 in the same memory block 302 have an array common source (ACS). In some examples, the drain of the drain selective transistor 310 of each memory string 306 is coupled to a corresponding bit line 318 (BL) from which data can be read or written via an output bus (not illustrated in FIG. 4). In some examples, each memory string 306 is configured to be selected or deselected by at least one of applying a select voltage (e.g., above the threshold voltage of the drain selective transistor 310) or deselect voltage (e.g., OV) to the respective drain selective transistor 310 via one or more drain selective lines (DSL) 314 or applying a select voltage (e.g., above the threshold voltage of the source selective transistor 308) or deselect voltage (e.g., OV) to the respective source selective transistor 308 via one or more source selective lines (SSL) 312.

As shown in FIG. 4, the memory string 306 may be organized into a plurality of memory blocks 302, each of which may have a source line 316 (e.g., a common SL coupled to ground). In some examples, each memory block 302 is a basic unit of data for performing an erase operation, e.g., all memory cells 304 on the same memory block 302 are erased simultaneously. To erase memory cells 304 in a selected memory block, a source line 316 coupled to the selected memory block and unselected memory blocks in the same plane as the selected memory block may be biased with an erase voltage Vers (e.g., a high positive voltage (e.g., 20 V or higher)). It should be understood that in some examples, the erase operation may be performed at a half memory block level, at a quarter memory block level, or at a level having any suitable number of memory blocks or any suitable fraction of the memory block. The memory cells 304 of adjacent memory strings 306 may be coupled by a word line 320 (WL) that selects which row of memory cells 304 is affected by read and program operations.

It should be noted that, for the SLC, each memory cell may store one bit of information, so that information stored in one layer of memory cells (for example, one physical page) at the physical level corresponds to information of one logical page. For the MLC, each memory cell may store two bits of information, so that information stored in one layer of memory cells (for example, one physical page) at the physical level corresponds to information of two logical pages. For the TLC, each memory cell may store three bits of information, so that information stored in a layer of memory cells (for example, one physical page) at the physical level corresponds to information of three logical pages. For the QLC, each memory cell may store four bits of information, so that information stored in a layer of memory cells (for example, one physical page) at the physical level corresponds to information of four logical pages.

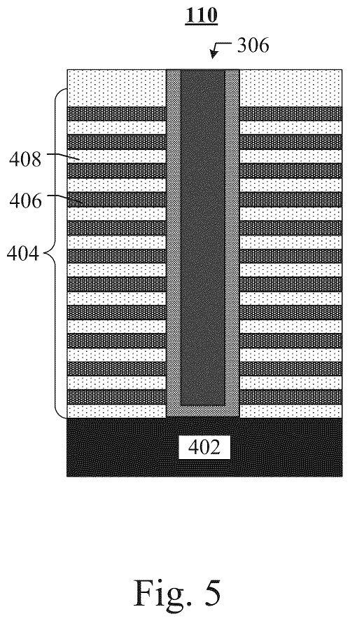

Referring to FIG. 5, FIG. 5 is a schematic cross-sectional view of a memory cell array including a memory string according to an example of the present disclosure. As shown in FIG. 5, a memory string 306 may extend vertically over the substrate 402 through the memory stacked layers 404. The substrate 402 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

The memory stacked layers 404 may include alternating gate conductive layers 406 and gate dielectric layers 408. The number of pairs of gate conductive layers 406 and gate dielectric layers 408 in the memory stacked layers 404 may represent the number of memory cells 304 in the memory cell array 110. The gate conductive layer 406 may include a conductive material including, but not limited to, tungsten (W), cobalt (Co), copper (Cu), aluminum (Al), polysilicon, doped silicon, silicide, or any combination thereof. In some examples, each gate conductive layer 406 includes a metal layer, such as a tungsten layer. In some examples, each gate conductive layer 406 includes a doped polysilicon layer. Each gate conductive layer 406 may include a control gate surrounding the memory cell 304, and may extend laterally at the top of the memory stacked layers 404 as a drain selective line 314, extend laterally at the bottom of the memory stacked layers 404 as a source selective line 312, or extend laterally between the drain selective line 314 and the source selective line 312 as a word line 320.

As shown in FIG. 5, the memory string 306 includes a channel structure extending vertically through the memory stacked layers 404. In some examples, the channel structure includes a channel hole filled with semiconductor material(s) (e.g., as semiconductor channels) and dielectric material(s) (e.g., as memory films). In some examples, the semiconductor channel includes silicon, e.g., polysilicon. In some examples, the storage film is a composite dielectric layer including a tunneling layer, a storage layer (also referred to as a “charge trapping/storage layer”), and a blocking layer. The channel structure may have a cylindrical shape (e.g., a pillar shape). According to some examples, the semiconductor channel, the tunneling layer, the storage layer, and the blocking layer are arranged in this order radially from the center of the pillar toward the outer surface of the pillar. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

According to some examples, a well (e.g., at least one of a P-well or a N-well) may be formed in the substrate 402, and a source terminal of the memory string 306 is in contact with the well. For example, a source line may be coupled to the well to apply an erase voltage to the well (e.g., the source of the memory string) during an erase operation. In some examples, the memory string 306 further includes a channel plug at a drain end of the memory string 306. It should be understood that although not illustrated in FIG. 5, additional components of the memory cell array 110 may be formed, including, but not limited to, gate line slits/source contacts, local contacts, interconnect layers, etc.

Referring back to FIG. 4, the peripheral circuit 112 may be coupled to memory cell array 110 through bit lines 318, word lines 320, source lines 316, source selective lines 312, and drain selective lines 314. The peripheral circuit 112 may include any suitable analog, digital, and mixed-signal circuit for facilitating operation of memory cell array 110 by applying at least one of voltage or current signals to and sensing at least one of voltage or current signals from each target memory cell 304 via bit lines 318, word lines 320, source lines 316, source selective lines 312, and drain selective lines 314. The peripheral circuit 112 may include various types of peripheral circuit formed using Metal Oxide Semiconductor (MOS) technology.

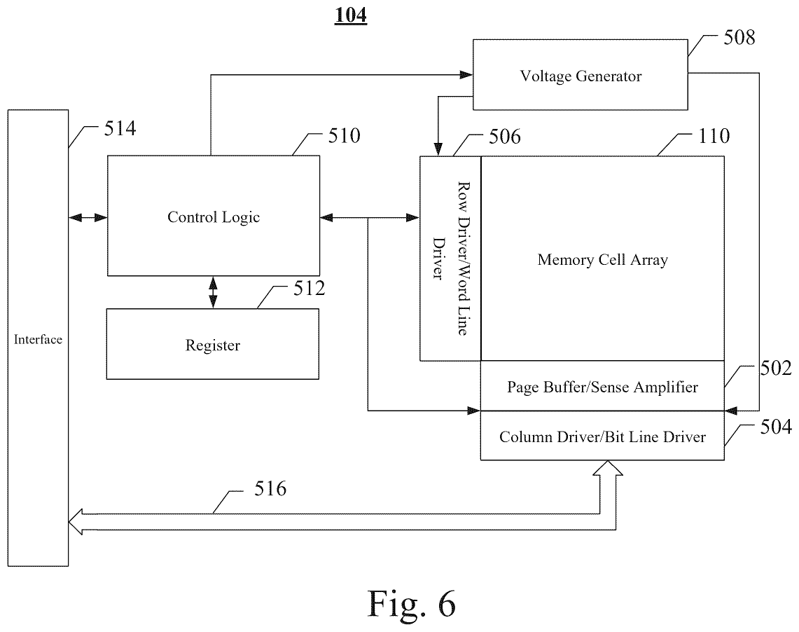

Referring to FIG. 6, FIG. 6 is a block diagram of a memory device including a peripheral circuit according to an example of the present disclosure. As shown in FIG. 6, the peripheral circuit includes a page buffer/sense amplifier 502, a column driver/bit line driver 504, a row driver/word line driver 506, a voltage generator 508, a control logic 510, a register 512, an interface (I/F) 514, and a data bus 516. It should be understood that, in some examples, additional peripheral circuits not illustrated in FIG. 6 may also be included.

Page buffer/sense amplifier 502 may be configured to read data from and program (write) data to the memory cell array 110 according to control signals from the control logic 510. In another example, the page buffer/sense amplifier 502 may perform a program verify operation to ensure that data has been correctly programmed into the memory cells 304 coupled to the selected word line 320. In yet another example, the page buffer/sense amplifier 502 may also sense low power signals from the bit line 318 representing data bits stored in memory cells 304 and amplify the small voltage swing to an identifiable logic level in a read operation. Column driver/bit line driver 504 may be configured to be controlled by the control logic 510 and to select one or more memory strings 306 by applying a bit line voltage generated from the voltage generator 508.

Row driver/word line driver 506 may be configured to be controlled by the control logic 510 and select/deselect memory blocks 302 of the memory cell array 110 and select/deselect word lines 320 of the memory block 302. Row driver/word line driver 506 may also be configured to drive a word line 320 using a word line voltage generated from the voltage generator 508. In some examples, the row driver/word line driver 506 may also select/deselect and drive the source selective line 312 and the drain selective line 314. As described in detail below, the row driver/word line driver 506 is configured to perform an erase operation on memory cells 304 coupled to the selected word line(s) 320. The voltage generator 508 may be configured to be controlled by the control logic 510 and generate word line voltages (e.g., read voltages, program voltages, pass voltages, local voltages, verify voltages, etc.), bit line voltages, and source line voltages to be supplied to the memory cell array 110.

Control logic 510 may be coupled to each peripheral circuit described above and configured to control operations of each peripheral circuit. Registers 512 may be coupled to the control logic 510 and include status registers, command registers, and address registers for storing status information, command opcodes (OP codes), and command addresses for controlling operations of each peripheral circuit. Interface 514 may be coupled to the control logic 510 and act as a control buffer, to buffer and relay control commands received from a host (not illustrated in FIG. 6) to control logic 510, and to buffer and relay status information received from the control logic 510 to the host. The interface 514 may also be coupled to the column driver/bit line driver 504 via the data bus 516 and act as a data input/output (I/O) interface and data buffer, to buffer and relay data to or from the memory cell array 110.

The basic principle for a three-dimensional NAND-type memory device is that: carriers (electrons or holes) across a charge barrier and inject a certain number of charges into a memory cell to complete a data writing process, and then stored data can be read according to a threshold voltage when the memory cell is turned on. Therefore, to read correct data, an error correction algorithm with strong error correction capability and high efficiency is usually introduced during data reading.

However, with the increase of the usage time, the charges stored in the memory cells will vary with the increase of the usage time, repeated read operations, cross temperatures, etc., which will affect the correctness of data reading. When the threshold voltage is significantly shifted upward or downward, the possibility of read errors will be very high when the original read voltage is used to read the data of the memory cell, and when the read errors exceed the error correction capability, it will also lead to the failure of reading the data of the memory cell, resulting in an uncorrectable error correction code (UECC) of the system product.

When the controller controls the memory device to perform a read operation, a default read operation (FW default read) is first performed on a memory cell of a corresponding physical address, wherein when the default read operation fails, a read retry operation (Read Retry) will be performed, when the read retry operation fails, a soft decode operation (Soft Decode) will be performed, and when the soft decode fails, a redundant array of independent disk (RAID) operation will be performed. When the RAID operation fails, the read operation stops, the read operation fails due to failure of error correction, and then the controller will send a read fail signal to the host. The read retry operation and the default read operation may be applied for hard decoding.

In some examples, the read retry operation may be performed by querying a retry table provided by the manufacturer. The read retry operation is essentially an error correction mechanism, wherein the retry table can provide a reference voltage for reading data. By querying the retry table and attempting to read each memory cell again using a read voltage that deviates from the normal threshold voltage while using error correction algorithms for error correction, attempts to read the data correctly are made. If data with a read error is corrected, the query on the retry table is stopped. If data with a read error is not corrected, then the query on the retry table is continued, until the entire retry table is traversed.

In the aforementioned read retry operation method, the retry table needs to be queried entry by entry, which inevitably increases the number of trial-and-error attempts, and consumes relatively long time. In addition, the retry table provided by the manufacturer only includes reference values under specific environmental conditions, while actual usage scenarios exhibit significant variations, so that many practical scenarios cannot be covered by the manufacturer-provided retry table, which may result in failure to correct data even after traversing data of the retry table. As a result, much time for processing commands is wasted. In summary, the method of performing read retry operations through repeated polling of the retry table not only prolongs processing time but also adversely affects the response time of subsequent commands, thereby compromising device performance.

In some other examples, after unsuccessful valley bottom voltage trial-and-error attempts using the retry table, a valley bottom voltage prediction function may be further employed. However, the valley bottom voltage prediction process typically requires considerable time consumption, as multiple iterations may be necessary to identify the optimal valley bottom voltage. This inefficiency may arise from error-prone selection of points during the valley bottom voltage prediction process, which can result in additional iteration cycles and degrade data recovery efficiency.

Based on one or more of the foregoing technical problems, examples of the present disclosure provide a memory device, an operating method thereof, and a memory system.

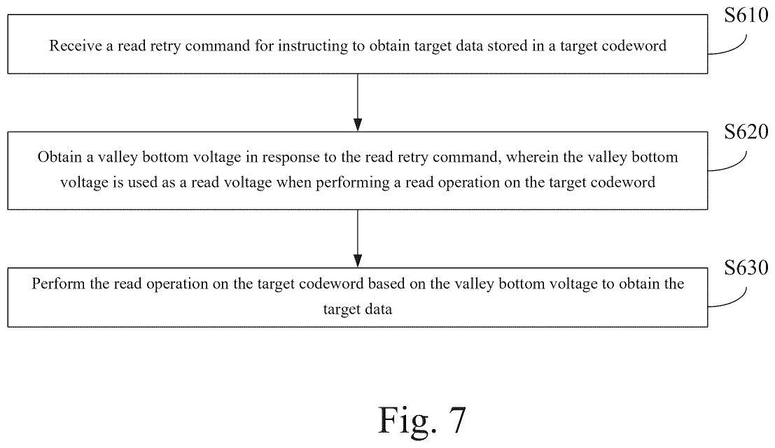

Referring back to FIG. 1 and FIG. 4, in a first aspect, an example of the present disclosure provides a memory device, wherein the memory device 104 includes: a memory cell array 110 including a plurality of memory cells 304, wherein a preset number of memory cells 304 among the plurality of memory cells 304 form a codeword; and a peripheral circuit 112 coupled to the memory cell array 110. Referring to FIG. 7, FIG. 7 is a schematic diagram of a process of an operating method that a memory system configured to perform according to an example of the present disclosure. As shown in FIG. 7, the peripheral circuit 112 is configured to:

At S610: receive a read retry command for instructing to obtain target data stored in a target codeword.

At S620: obtain a valley bottom voltage in response to the read retry command, wherein the valley bottom voltage is used as a read voltage when performing a read operation on the target codeword.

At S630: perform the read operation on the target codeword based on the valley bottom voltage to obtain the target data.

Here, for the structure of the memory device 104, reference may be made to the related description above, and details are not described herein again.

In some examples, the memory device 104 includes: a memory cell array 110 including a plurality of memory blocks 302; a plurality of word lines 320 coupled to the memory blocks 302, wherein each of the word lines 320 is coupled to a plurality of memory cells 304 in the memory block 302. All memory cells 304 coupled to one word line 320 form one physical page. A preset number of memory cells 304 form a codeword (CW). A physical page may include one or more codewords.

In some examples, the number of memory cells included in one codeword is the same as the number of memory cells for one error correction encoding or decoding when the encoding or decoding is performed thereon. In some examples, the number of memory cells included in one codeword may be less than or equal to the number of memory cells coupled to one physical page. For example, the number of memory cells included in one codeword is ¼ of the number of memory cells coupled to one physical page. In other examples, the number of memory cells included in the codeword may range from 24 to 212. For example, the codeword may include 24, 28, or 212 memory cells.

In some examples, a codeword may be determined as a reference codeword, and the number of memory cells included in one codeword may be less than or equal to the number of memory cells coupled to one physical page. In other words, when the number of memory cells included in a codeword is the same as the number of memory cells coupled to a physical page, a certain word line can be determined as a reference word line, and a read operation can be performed on the reference word line to obtain a first result as a characteristic value.

In some examples, a certain codeword to be read may be determined as a target codeword, and a read operation is performed on the target codeword using the valley bottom voltage to obtain target data in the target codeword.

In summary, different memory systems may select codewords of different sizes to meet their performance, reliability, and storage requirements. Memory cells (e.g., MLC, TLC, or QLC) in different types of memory devices may store different numbers of bits. It may be understood that the codeword may include a plurality of memory cells, and the number of memory cells included in the codeword may be adjusted according to an actual situation.

It should be noted that in practice, the codeword may have some additional reserved space for management and error correction, and therefore the number of actually required memory cells may slightly exceed the calculation result.

In the example of the present disclosure, at operation S610, the control logic 510 is configured to receive a read retry command for instructing to obtain target data stored in a target codeword. Here, the read retry command is essentially an error correction mechanism, and the read retry command may be performed after the default read operation using the default read voltage fails.

In some examples, the memory cell array 110 includes a configuration block configured to store a mapping table, and wherein the control logic 510 is configured to store the mapping table in the configuration block into a register 512 when the memory device 104 undergoes Power On Reset (POR), and the peripheral circuit 112 includes the register 512 configured to store the mapping table.

Here, a mapping table is needed in the process of querying and obtaining the valley bottom voltage and is stored in the configuration block of the memory cell array 110, and when the memory device 104 undergoes Power On Reset and is initialized, the mapping table in the configuration block is loaded into the register 512 for use by the control logic 510.

Here, reference may be made to the related description of FIG. 6 for the register 512, and the meaning of the configuration block will be explained below. The memory cell array 110 includes at least a configuration block and other blocks, for example, a data block, a dedicated test block, and a backup block. The configuration block may be configured to store various configuration information, for example, a mapping table which is needed to obtain the valley bottom voltage in an example of the present disclosure, a parameter related to column repair, a parameter related to a bad block, a parameter related to trimming, contents related to embedded firmware repair mechanism (eREM), and the like. For example, the trimming parameters may include operation parameters of the NAND, such as voltage, current, temperature compensation, and power etc. The trimming parameter may include at least a static trimming parameter (Static Trim) and a trimming parameter (Parameter Trim), wherein the Static Trim may directly modify some parameters of the peripheral circuit, and the Parameter Trim may be first read by the firmware and then correspondingly modify some parameters of the peripheral circuit.

In the test flow before leave the factory, the key information of the memory device is stored in the configuration block, and then when the memory device leaves the factory for use, the memory device is configured by using the Power On Reset command. In the configuration process, the key information of the memory device in the configuration block may be loaded into a corresponding register in the peripheral circuit, and when the loading is completed, various operations may be performed on the memory device 104.

In some examples, the peripheral circuit 112 further includes: a control logic 510 coupled to the register 512 and configured to: receive the read retry command; obtain the valley bottom voltage based on the target codeword and the mapping table; and perform the read operation on the target codeword based on the valley bottom voltage to obtain the target data. Here, the memory device 104 may obtain the valley bottom voltage after receiving the read retry command, and perform the read operation based on the valley bottom voltage to obtain the target data stored in the target codeword. For example, the process of finding the valley bottom voltage is done entirely by the memory device 104 without relying on any input or determination provided by the controller 106, e.g., the entire process converges inside the memory device 104.

In some examples, the peripheral circuit 112 further includes a latch coupled to the control logic 510, and wherein the control logic 510 is configured to store the target data into the latch. Here, the latch may serve as an interface for information interaction between the memory device 104 and the outside (for example, the controller 106 in FIG. 1), and after the read operation is performed using the valley bottom voltage, the target data stored in the target codeword may be stored in the latch from which the controller 106 may obtain the target data.

In some examples, the number of bits stored in memory cell is M, the stored M bits correspond to 2^{M}−1 read levels comprising a reference read level, and M is an integer greater than or equal to 2.

In some examples, the memory cell array 110 includes memory cells 304 which store M bits, the stored M bits correspond to M pages respectively, and M bits of data of the M-bit memory cells 304 is read through Q read voltages (e.g., Q read levels), wherein M and Q are integers greater than or equal to 2, and Q=2^{M}−1.

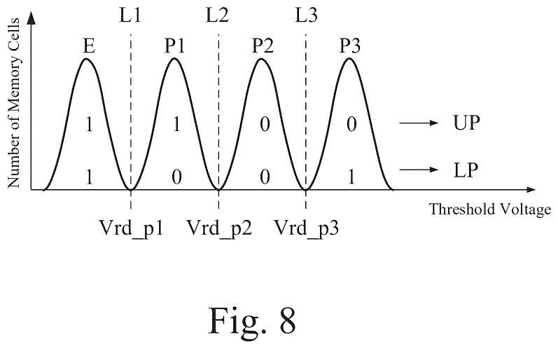

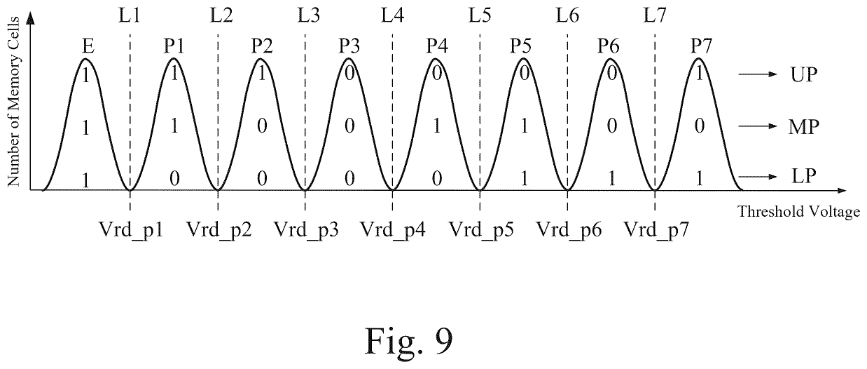

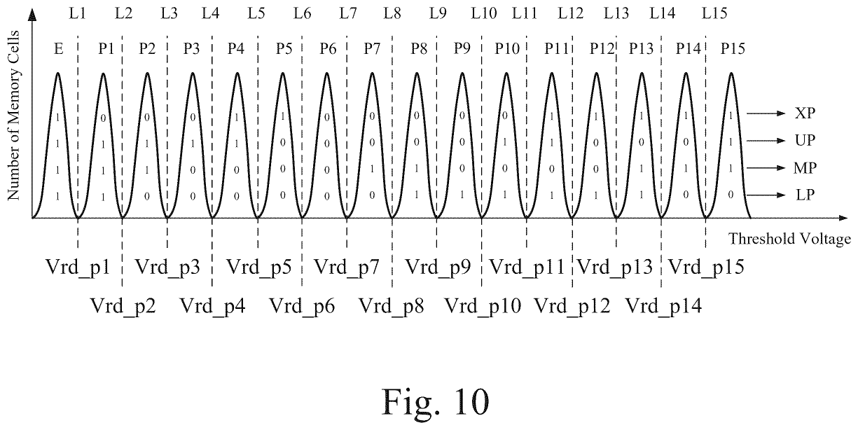

Referring to FIG. 8 to FIG. 10, FIG. 8, FIG. 9 and FIG. 10 are threshold voltage distribution diagrams corresponding to memory cells that store two bits, three bits, and four bits according to examples of the present disclosure, respectively. The following provides example descriptions with reference to FIG. 8 to FIG. 10.

In some examples, when the memory cell stores two bits, the corresponding memory states include states 0-3. Referring to FIG. 8, among the above four states, the state 0 is the erased state E, and the state 1, the state 2 and the state 3 are the first programmed state P1, the second programmed state P2 and the third programmed state P3, respectively. The binary data corresponding to the above four states are respectively 11, 10, 00, and 01. Correspondingly, the memory device includes two pages: a lower page (LP) and an upper page (UP). Here, the stored two bits corresponding to the four states are stored in the lower page and the upper page respectively.

Taking the memory cell shown in FIG. 8 as an example, the stored two bits of the 2-bit memory cell is read through three read levels (a first read level L1, a second read level L2 and a third read level L3, as shown in FIG. 8), and the three read levels respectively correspond to three read voltages, for example, a first read voltage Vrd_p1, a second read voltage Vrd_p2 and a third read voltage Vrd_p3. As shown in FIG. 8, the binary data corresponding to the lower page is 1001, and the corresponding first read voltage Vrd_p1 and third read voltage Vrd_p3 are needed to read the lower page. The binary data corresponding to the upper page is 1100, and the corresponding second read voltage Vrd_p2 is needed to read the upper page.

For example, when the memory cell stores three bits, the corresponding memory states include states 0-7. Referring to FIG. 9, among the above eight states, the state 0 is the erased state E, the state 1, the state 2, the state 3, . . . , and the state 7 are the first programmed state P1, the second programmed state P2, the third programmed state P3, . . . , and the seventh programmed state P7, respectively. The binary data corresponding to the eight states are respectively 111, 110, 100, 000, 010, 011, 001, and 101. Correspondingly, the memory device includes three pages: a lower page, a middle page (MP), and an upper page. Here, the stored three bits corresponding to the eight states are respectively stored in the lower page, the middle page and the upper page.

Taking the memory cell illustrated in FIG. 9 as an example, the stored three bits of the 3-bit memory cell is read through seven read levels (a first read level L1, a second read level L2, a third read level L3, a fourth read level L4, a fifth read level L5, a sixth read level L6 and a seventh read level L4, as shown in FIG. 9), and the seven read levels respectively correspond to seven read voltages, for example, a first read voltage Vrd_p1, a second read voltage Vrd_p2, a third read voltage Vrd_p3, a fourth read voltage Vrd_p4, a fifth read voltage Vrd_p5, a sixth read voltage Vrd_p6 and a seventh read voltage Vrd_p7. The lower page corresponds to two read voltages, the middle page corresponds to three read voltages, and the upper page corresponds to two read voltages. As shown in FIG. 9, the binary data corresponding to the lower page is 10000111, and the corresponding first read voltage Vrd_p1 and fifth read voltage Vrd_p5 are needed to read the lower page. The binary data corresponding to the middle page is 11001100, and the corresponding second read voltage Vrd_p2, fourth read voltage Vrd_p4 and sixth read voltage Vrd_p6 are needed to read the middle page. The binary data corresponding to the upper page is 11100001, and the corresponding third read voltage Vrd_p3 and seventh read voltage Vrd_p7 are needed to read the upper page.

In some examples, when the memory cell stores four bits, the corresponding memory states include states 0-15. Referring to FIG. 10, among the above sixteen states, the state 0 is the erased state E, the state 1, the state 2, the state 3, . . . , and the state 15 are the first programmed state P1, the second programmed state P2, the third programmed state P3, . . . , and the fifteenth programmed state P15, respectively. The binary data corresponding to the sixteen states are respectively 1111, 0111, 0110, 0100, 1100, 1000, 0000, 0010, 0011, 0001, 0101, 1101, 1001, 1011, 1010, and 1110. Correspondingly, the memory device includes four pages, which are a lower page, a middle page, an upper page, and an extra page (XP). Here, the stored four bits corresponding to the sixteen states are respectively stored in the lower page, the middle page, the upper page, and the extra page.

Taking the memory cell illustrated in FIG. 10 as an example, the stored four bits of the 4-bit memory cell is read through fifteen read levels (a first read level L1, a second read level L2, a third read level L3, a fourth read level L4, a fifth read level L5, a sixth read level L6, a seventh read level L7, an eighth read level L8, a ninth read level L9, a tenth read level L10, an eleventh read level L10, a twelfth read level L2, a thirteenth read level L3, a fourteenth read level L4, and a fifteenth read level L5, as shown in FIG. 10), and the fifteen read levels respectively correspond to fifteen read voltages, for example, a first read voltage Vrd_p1, a second read voltage Vrd_p2, a third read voltage Vrd_p3, a fourth read voltage Vrd_p4, a fifth read voltage Vrd_p5, a sixth read voltage Vrd_p6, a seventh read voltage Vrd_p7, an eighth read voltage Vrd_p8, a ninth read voltage Vrd_p9, a tenth read voltage Vrd_p10, an eleventh read voltage Vrd_p11, a twelfth read voltage Vrd_p12, a thirteenth read voltage Vrd_p13, a fourteenth read voltage Vrd_p14, and a fifteenth read voltage Vrd_p15. The lower page corresponds to three read voltages, the middle page corresponds to four read voltages, the upper page corresponds to four read voltages, and the extra page corresponds to four read voltages. As shown in FIG. 10, the binary data corresponding to the lower page is 1100000011111100, and the corresponding second read voltage Vrd_p2, eighth read voltage Vrd_p8 and fourteenth read voltage Vrd_p14 are needed to read the lower page. The binary data corresponding to the middle page is 1110000110000111, and the corresponding third read voltage Vrd_p3, seventh read voltage Vrd_p7, ninth read voltage Vrd_p9 and thirteenth read voltage Vrd_p13 are needed to read the middle page. The binary data corresponding to the upper page is 1111100000110001, and the corresponding fifth read voltage Vrd_p5, tenth read voltage Vrd_p10, twelfth read voltage Vrd_p12 and fifteenth read voltage Vrd_p15 are needed to read the upper page. The binary data corresponding to the extra page is 1000110000011111, and the corresponding first read voltage Vrd_p1, fourth read voltage Vrd_p4, sixth read voltage Vrd_p6 and eleventh read voltage Vrd_p11 are needed to read the extra page.

The lower page is usually closest to the source/drain terminal, so the valley bottom voltage of each level of read voltages corresponding to the lower page is preferentially determined, such that the access speed is the fastest, the response time is the shortest, and the balance performance and durability in the data access process can be ensured. It should be noted that the manner of preferentially determining the valley bottom voltage of each level of read voltages corresponding to the lower page is merely an example, and is not used to limit a determination order of valley bottom voltages of each level of read voltages in multiple levels of read voltages corresponding to at least some pages in an example of this application.

In some examples, the control logic 510 is configured to: obtain a first result corresponding to a reference codeword at a reference read voltage of the reference read level as a characteristic value, wherein the first result is to indicate the number of bits flipped between two read results of the reference codeword at a first read voltage and a second read voltage, and a difference value between the first read voltage and the second read voltage is less than a preset voltage. In an example of the present disclosure, the first result (which may also be referred to as fail bit count (FBC)) of the reference codeword at the reference read level is used as a characteristic value (Vt indicator) which is to indicate the offset degree of the threshold voltage of the memory cell at the target read level.

The following describes the meaning of the first result and the manner of obtaining the first result.

In some examples, in the process of performing a read operation on the memory device, one read operation reads data of one physical page. When the number of memory cells included in one codeword may be less than the number of memory cells coupled to one physical page, the codeword is a basic unit for obtaining the first result, though a plurality of codewords are not excluded. For example, the first result corresponding to at least one reference codeword at the reference read voltage may be obtained, e.g., the first result corresponding to the at least one reference codeword at the reference read voltage of the reference read level is obtained. For example, one physical page may correspond to four codewords, hardware operations of the page buffer may count the fail bit counts (FBC) of the four codewords respectively at a time, then the FBCs of the four codewords are summed to obtain the FBC for one physical page, and subsequent calculation will use the summed value. It may be understood that the first result herein may be based on the FBC data for one physical page which may correspond to a plurality of reference codewords.

Here, the first read voltage and the second read voltage are both generalized concepts, and the difference value between the first read voltage and the second read voltage is less than a preset voltage. In obtaining the first result corresponding to the reference codeword, the reference read voltage of the reference read level is the first read voltage, and the second read voltage may be obtained by adjusting the first read voltage. The first read voltage may be determined based on the default read voltage of the reference read level, for example, the first read voltage may be the default read voltage of the reference read level, and in this case, a difference value between the first read voltage and the default read voltage of the reference read level is 0. Alternatively, the first read voltage may be obtained by adjusting the default read voltage of the reference read level, and the first read voltage may be greater than the default read voltage of the reference read level or the first read voltage may be less than the default read voltage of the reference read level. It should be noted that the reference read level is selected from one of a plurality of read levels, a default read voltage for each of the plurality of read levels is pre-stored in the memory device, and the default read voltage is the read voltage when the threshold voltage has not shifted. In some examples, the second read voltage may be greater than the first read voltage, and the difference value between the first read voltage and the second read voltage may range from 5 mV to 20 mV. For example, the difference value between the first read voltage and the second read voltage may comprise 5 mV, 10 mV, 15 mV, and 20 mV. In some other examples, the second read voltage may be less than the first read voltage, and difference value between the first read voltage and the second read voltage may range from −5 mV to −20 mV. For example, the difference value between the first read voltage and the second read voltage may comprise −5 mV, −10 mV, −15 mV, and −20 mV.

In some examples, the control logic 510 is configured to: read data stored in the reference codeword at the first read voltage to obtain a second result; read data stored in the reference codeword at the second read voltage to obtain a third result; perform a logical operation on the second result and the third result to obtain a fourth result; and count the number of bits in the fourth result indicating that the third result is flipped relative to the second result, to obtain the first result.

Here, the first read voltage and the second read voltage are sequentially related, for example, the second read voltage is obtained by adjusting the first read voltage. Based on this, the difference value between the first read voltage and the second read voltage is the step size. In some examples, the step size ranges from 5 mV to 20 mV, for example, the step size may comprise 5 mV, 10 mV, 15 mV or 20 mV. The preset voltage is related to the step size, and may be a voltage slightly greater than the step size. In some examples, the preset voltage may range from 6 mV to 21 mV. For example, the preset voltage may comprise 6 mV, 11 mV, 16 mV, or 21 mV. In some other examples, the preset voltage may range from −6 mV to −21 mV. For example, the preset voltage may comprise −6 mV, −11 mV, −16 mV, or −21 mV.

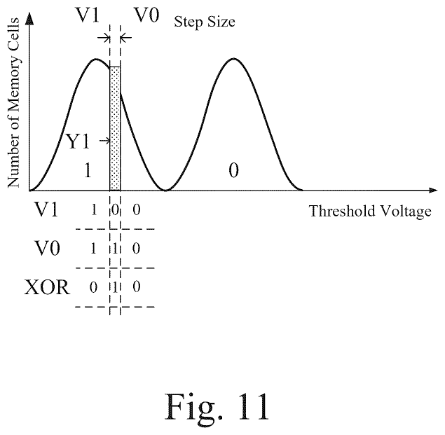

Referring to FIG. 11, FIG. 11 is a threshold voltage distribution diagram corresponding to a memory cell when obtaining a first result according to an example of the present disclosure. In the example of the present disclosure, the first result corresponding to a specific voltage (for example, the first read voltage V0 shown in FIG. 11) may be understood as: after adjusting a specific voltage, e.g., a voltage difference existing between the specific voltage and the adjusted specific voltage, such as the second read voltage V1 in FIG. 11, the number of bits flipped between two read results obtained at the specific voltage and the adjusted specific voltage in a predetermined number of memory cells serves as the first result corresponding to the specific voltage. The predetermined number of memory cells may form a code word.

In an example of the present disclosure, the peripheral circuit 112 is configured to: perform a read operation on the reference codeword to obtain a first result as a characteristic value, wherein the first result is to indicate the number of bits flipped between two read results of the reference codeword at a first read voltage and a second read voltage, and a difference value between the first read voltage and the second read voltage is less than a preset voltage.

In some examples, the peripheral circuit 112 is configured to: in a single-level read (SLR) mode, obtain a first result corresponding to the reference codeword at a reference read voltage (for example, a default read voltage) of a reference read level as a characteristic value, wherein the default read voltage is a read voltage when a threshold voltage is not shifted.

In some examples, the memory device 104 is configured to: enter a single level read mode in response to the mode setting command; and in the single-level read mode, obtain a first result corresponding to the reference codeword at a reference read voltage (for example, a default read voltage) of a reference read level.

The normal read mode and the single-level read mode will be explained below with reference to FIG. 9 and FIG. 11 by taking TLC as an example.

Before introducing the single-level read mode, the normal read mode is first explained. Performing a normal read operation on a TLC includes sequentially performing read operations on a lower page, a middle page, and an upper page. Here, during the read operation on the lower page, the read operations using the first read voltage Vrd_p1 and the fifth read voltage Vrd_p5 may be sequentially performed. When performing the read operation at the first read voltage Vrd_p1, memory cells with threshold voltages less than the first read voltage Vrd_p1 are turned on, and memory cells with threshold voltages greater than the first read voltage Vrd_p1 are turned off. Thus, data “1” may be read from memory cells with threshold voltages less than the first read voltage Vrd_p1, and data “0” may be read from memory cells with threshold voltages greater than the first read voltage Vrd_p1.

Since the first read voltage Vrd_p1 is the minimum read voltage among the read voltages for identifying the lower page data, the data “1” read from the memory cells with threshold voltages less than the first read voltage Vrd_p1 is confirmed data. For example, data “1” may be read from the memory cells in the erased state E and having threshold voltages less than the first read voltage Vrd_p1. Since the read operation on the lower page is completed by further performing the read operation using the fifth read voltage Vrd_p5, the data “0” read from the memory cells with threshold voltages greater than the fifth read voltage Vrd_p5 is not confirmed data.

When performing the read operation using the fifth read voltage Vrd_p5, a ground voltage may be applied to bit lines corresponding to memory cells which are in the erased state E and have confirmed data, and a precharge voltage may be applied to the remaining bit lines. When performing the read operation using the fifth read voltage Vrd_p5, data “1” may be read from the memory cells in the programmed states P1-P4, and data “0” may be read from the memory cells in the programmed states P5-P7. According to the algorithm of the lower page read operation, the data read using the fifth read voltage Vrd_p5 may be flipped and stored in the page buffer, and thus, the data read from the memory cells in the programmed states P1-P4 and having threshold voltages less than the fifth read voltage Vrd_p5 may be determined as “0”, and the data read from the memory cells in the programmed states P5-P7 and having threshold voltages greater than the fifth read voltage Vrd_p5 may be determined as “1”.

Here, when the read operation on the lower page ends, the read operation on the middle page may be performed. During the read operation on the middle page, the read operations using the second read voltage Vrd_p2, the fourth read voltage Vrd_p4, and the sixth read voltage Vrd_p6 may be sequentially performed. When a read operation using the second read voltage Vrd_p2 is performed, data “1” may be read from memory cells with threshold voltages less than the second read voltage Vrd_p2, and data “0” may be read from memory cells with threshold voltages greater than the second read voltage Vrd_p2.

Since the second read voltage Vrd_p2 is the minimum read voltage among the read voltages for identifying the middle page data, the data “1” read from memory cells with threshold voltages less than the second read voltage Vrd_p2 is confirmed data. For example, the data “1” may be read from memory cells in the erased state E and the first programmed state P1 and having threshold voltages less than the second read voltage Vrd_p2. Since the read operation on the middle page is completed by further performing the read operation using the fourth read voltage Vrd_p4 and the sixth read voltage Vrd_p6, the data “0” read from the memory cells with threshold voltages greater than the fourth read voltage Vrd_p4 is not confirmed data.

When performing a read operation using the fourth read voltage Vrd_p4, a ground voltage may be applied to bit lines corresponding to memory cells which are in the erased state E and the first programmed state P1 and have confirmed data, and a precharge voltage may be applied to the remaining bit lines. When performing the read operation using the fourth read voltage Vrd_p4, data “1” may be read from memory cells in the programmed states P2 and P3, and data “0” may be read from memory cells in the programmed states P4-P7. According to the algorithm of the middle page read operation, the data read using the fourth read voltage Vrd_p4 may be flipped and stored in the page buffer, and thus, the data read from the memory cells in the programmed states P2 and P3 and having threshold voltages less than the fourth read voltage Vrd_p4 may be determined as “0”, and the data read from the memory cells in the programmed states P4-P7 and having threshold voltages greater than the fourth read voltage Vrd_p4 may be determined as “1”.

Since the read operation on the lower page is completed by further performing the read operation using the sixth read voltage Vrd_p6, the data “1” read from the memory cells with threshold voltages greater than the sixth read voltage Vrd_p6 is not confirmed data.

When performing a read operation using the sixth read voltage Vrd_p6, a ground voltage may be applied to bit lines corresponding to memory cells in the erased state E and the programmed states P1-P3 and having confirmed data, and a precharge voltage may be applied to the remaining bit lines. When performing a read operation using the sixth read voltage Vrd_p6, data “1” may be read from memory cells in the programmed states P4 and P5 and having threshold voltages less than the sixth read voltage Vrd_p6, and data “0” may be read from memory cells in the programmed states P6 and P7.

Here, when the read operation on the middle page ends, the read operation on the upper page may be performed. In the read operation on the upper page, the read operations using the third read voltage Vrd_p3 and the seventh read voltage Vrd_p7 may be sequentially performed. When performing the read operation using the third read voltage Vrd_p3, data “1” may be read from memory cells with threshold voltages less than the third read voltage Vrd_p3, and data “0” may be read from memory cells with threshold voltages greater than the third read voltage Vrd_p3.

Since the third read voltage Vrd_p3 is the minimum read voltage among the read voltages for identifying the upper page data, the data “1” read from memory cells with threshold voltages less than the third read voltage Vrd_p3 is confirmed data. For example, the data “1” may be read from memory cells in the erased state E, the programmed state P1 and P2 and having threshold voltages less than the third read voltage Vrd_p3. Since the read operation on the upper page is completed by further performing the read operation using the seventh read voltage Vrd_p7, the data “0” read from memory cells with threshold voltages greater than the seventh read voltage Vrd_p7 is not confirmed data.

When performing a read operation using the seventh read voltage Vrd_p7, a ground voltage may be applied to bit lines corresponding to memory cells which are in the erased state E, the programmed states P1 and P2 and have confirmed data, and a precharge voltage may be applied to the remaining bit lines. When the read operation using the seventh read voltage Vrd_p7 is performed, data “1” may be read from the memory cells in the programmed states P3-P6, and data “0” may be read from the memory cells in the seventh programmed state P7. According to the algorithm of the upper page read operation, the data read using the seventh read voltage Vrd_p7 may be flipped and stored in the page buffer, and thus, the data read from the memory cells in the programmed states P3-P6 and having threshold voltages less than the seventh read voltage Vrd_p7 may be determined as “0”, and the data read from the memory cells in the seventh programmed state P7 and having threshold voltages greater than the seventh read voltage Vrd_p7 may be determined as “1”.

It should be noted that since the TLC includes eight states, a read voltage group which includes seven read voltages is required to perform a normal read mode on the TLC and distinguish among the above eight states. Only after all the read voltages in the read voltage group are used, a read result may be obtained, wherein the read result refers to specific data stored in a certain memory cell. For example, the stored three bits of data stored in a certain memory cell may be read as “101”.

However, the single-level read mode refers to performing a read operation using one read voltage of a plurality of read voltages included in a read voltage group, to obtain the number of memory cells with threshold voltages greater than or equal to the read voltage and the number of memory cells with threshold voltages less than the read voltage as the read result. Data of memory cells with threshold voltages less than the read voltage may be determined as “1”, and data of memory cells with threshold voltages greater than or equal to the read voltage may be determined as “0”. Of course, “1” and “0” here do not represent the data actually stored in the memory cell, and memory cells are classified only according to the relationship between the magnitudes of the read voltage and the threshold voltages of the memory cells. Memory cells with threshold voltages less than the read voltage are regarded as first type of memory cells, and the data stored in the first type of memory cells is regarded as “1”; and memory cells with threshold voltages greater than or equal to the read voltage are regarded as second type of memory cells, and the data stored in the second type of memory cells is regarded as “0”.

In some examples, the data stored in the reference codeword is read at the first read voltage to obtain a second result. For example, referring to FIG. 11, the data stored in the reference codeword is read at the first read voltage V0 to obtain the second result. In some examples, memory cells with threshold voltages less than the first read voltage V0 are marked as “1”, and memory cells with threshold voltages greater than the first read voltage V0 are marked as “0”, thereby obtaining the second result.

Then, the first read voltage is adjusted to obtain a second read voltage, and the data stored in the reference codeword is read at the second read voltage. For example, referring to FIG. 11, the first read voltage V0 is adjusted, and the data stored in the reference codeword is read at the second read voltage V1 which is adjusted to obtain a third result. In some examples, memory cells with threshold voltages less than the second read voltage V1 are marked as “1”, and memory cells with threshold voltages greater than the second read voltage V1 are marked as “0”, thereby obtaining the third result.

Then, a logical operation is performed on the second result and the third result to obtain a fourth result. For example, referring to FIG. 11, an exclusive OR (XOR) operation is performed on the second result and the third result to obtain the fourth result.

It should be noted that the XOR operation is one of basic logic operations. In binary operations, a result is “0” if two binary numbers at the same position are the same, and a result is “1” if two binary numbers at the same position are different (for example, “0” for same, “1” for different).

Then, the number of bits in the fourth result indicating that the third result is flipped relative to the second result is counted to obtain the first result. For example, referring to FIG. 11, “1” in the fourth result represents the number of memory cells with different threshold voltages between the first read voltage V0 and the second read voltage V1. In other words, “1” in the fourth result represents the number of bits flipped between two read results of the reference codeword at the first read voltage V0 and the second read voltage V1, and the number of “1” is denoted as the first result corresponding to the first read voltage V0.

In some examples, a read level with a moderate threshold voltage offset degree may be selected among Q read levels as the reference read level, for example, the Q read levels include the reference read level, for example, the reference read level is selected from one of the Q read levels. The read level with the moderate threshold voltage offset degree is selected as the reference read level, so that the characteristic value at the reference read level is more representative and more conducive to increase the accuracy of determining the valley bottom voltage in the future.

Taking TLC as an example for illustration, from the second read level L2 to the seventh read level L7, the shift degrees of the threshold voltages of the memory cells sequentially increase. Therefore, as the shift degree of the threshold voltage of the memory cell at the fourth read level L4 is moderate, the fourth read level L4 may be considered to be selected as the reference read level. It should be noted that the above only uses the shift degrees of the threshold voltages of the memory cells at various read levels of TLC in a specific application scenario as an example for explanation, and does not mean that only the fourth read level L4 can be selected as the reference read level in TLC. In other application scenarios of TLC, the third read level L3 or the fifth read level L5 may also selected as the reference read level. There is no limitation on which read level is selected from the plurality of read levels as the reference read level, and it is needed to be determined in combination with an application scenario.

In some examples, the control logic 510 is configured to: obtain a characteristic level (Vt indicator grade) corresponding to the characteristic value based on the characteristic value, wherein the characteristic level is to indicate one or more continuously arranged characteristic values.

As described above, the characteristic value refers to the first result, e.g., the FBC. For example, the characteristic values may take various numerical values, such as 211, 107, 86, 53, or the like. If a mapping table is created using a characteristic value as one of the influencing factors, the storage capacity occupied by the mapping table may be large. Therefore, grouping or segmentation processing may be performed on the characteristic values to obtain a characteristic level, wherein the characteristic level is to indicate one or more continuously arranged characteristic values. When each characteristic level indicates one characteristic value, the number of characteristic levels is the same as the number of characteristic values. When each characteristic level indicates a plurality of continuously arranged characteristic values, the number of characteristic levels is smaller than the number of characteristic values, so as to reduce the storage capacity occupied by the mapping table and facilitate group management or segment management of data.

For example, each characteristic level is to indicate 10 continuously arranged characteristic values. Characteristic level 1 may represent characteristic values 0 through 9, characteristic level 2 may represent characteristic values 10 through 19, and so on, and characteristic level 22 may represent characteristic values 210 through 219. In one example, operation S610 is performed, and the obtained characteristic value is 211, and then it may be determined that the characteristic level is 22. The number of continuously arranged characteristic values that a characteristic level indicates is not limited in the present disclosure, and each characteristic level may include 2, 5, 8, 10, 15, or 20 continuously arranged characteristic values.

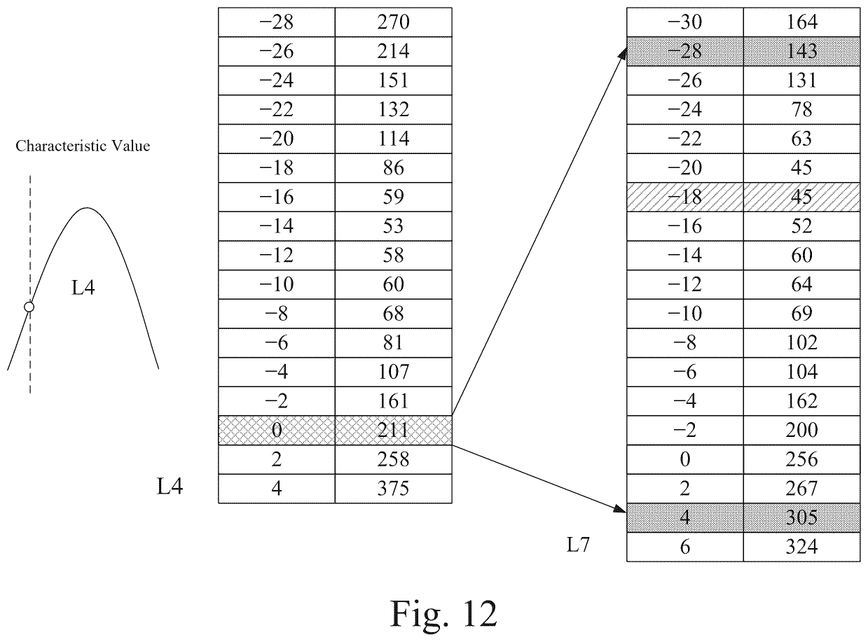

Referring to FIG. 12, FIG. 12 is a schematic diagram of determining a characteristic level according to an example. As shown in FIG. 12, when the reference read level is the fourth read level L4, the first result corresponding to the reference codeword at the default read voltage (e.g., DAC=0) of the fourth read level L4 is obtained as 211, and the characteristic value is determined as 211. When the number of continuously arranged characteristic values that a characteristic level indicates is 10, it may be determined that the characteristic level is 22 based on the characteristic value being 211.

In some examples, the control logic 510 is configured to: determine a word line group corresponding to the target codeword based on a position of the target codeword in the memory cell array, wherein the word line group is to indicate one or more word lines disposed adjacently.

Here, different word lines have different positions in the memory cell array, and therefore, shift degrees of threshold voltages of memory cells coupled to different word lines are different. If the word line is used as one of the influencing factors to create the mapping table, the storage capacity occupied by the mapping table is large. Therefore, grouping of word lines may be considered to obtain word line groups, which are used to represent one or more word lines disposed adjacently. When each word line group indicates one word line, the number of word line groups is the same as the number of word lines. When each word line group indicates a plurality of word lines disposed adjacently, the number of word line groups is smaller than the number of word lines, so that the storage capacity occupied by creating a mapping table using the word line groups is reduced, and grouping management of data is facilitated.

Here, word lines with the same threshold voltage shift patterns may be managed as the same word line group, and within the same word line group, offset predictions at different characteristic levels and different read levels are managed. In other words, with the same other conditions, the shift degrees of the threshold voltages in different word line groups have different patterns. For example, each word line group indicates 50 word lines disposed adjacently, wherein word line group 1 may represent word lines WL1 to WL50, and word line group 2 may represent word lines WL51 to WL100. The number of word lines disposed adjacently that a word line group indicates is not limited in the present disclosure, and each word line group may include 10, 20, 30, 40, or 50 word lines disposed adjacently.

In some examples, the control logic 510 is configured to: determine at least one offset prediction based on the characteristic level, a target read level of the target codeword, and the word line group corresponding to the target codeword in combination with the mapping table, wherein the mapping table comprises a mapping relationship among the characteristic level, the target read level, the word line group, and the offset prediction; and obtain the valley bottom voltage based on the at least one offset prediction.

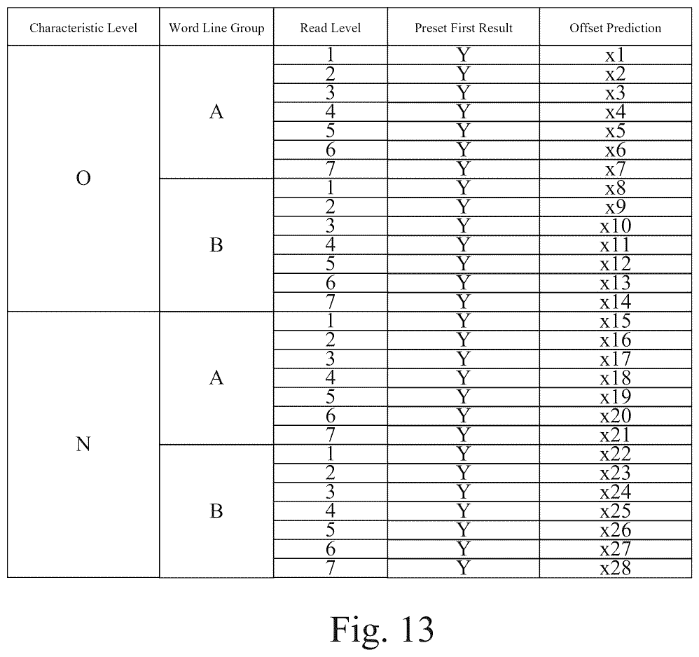

Referring to FIG. 13, FIG. 13 is a schematic diagram of a mapping table according to an example of the present disclosure. As shown in FIG. 13, column 1 indicates characteristic levels (Vt indicator level), column 2 indicates WL groups, column 3 indicates target read levels, and column 5 indicates offset predictions. The characteristic level, the word line group, and the target read level may be respectively considered as one of the influence factors for determining the offset prediction, and at least one offset prediction (for example, x20) is determined by looking up the mapping table based on the characteristic level (for example, the characteristic level N), the word line group (for example, the word line group A), and the target read level (for example, the target read level L6) that are determined as described above.

In some examples, the at least one offset prediction comprises two offset predictions, and two preset first results corresponding to the two preset offsets are both within a preset interval, and wherein the control logic 510 is configured to: determine two target read voltages based on the two offset predictions; obtain a first result corresponding to the target codeword at one of the target read voltages, and obtain a first result corresponding to the target codeword at the other one of the target read voltages; and obtain the valley bottom voltage based on the two target read voltages and two corresponding first results in combination with a preset function model.

With reference to FIG. 12 and FIG. 13, at least one offset prediction (for example, x21) is determined by looking up the mapping table based on the characteristic level (for example, the characteristic level N), the word line group (for example, the word line group A), and the target read level (for example, the target read level L7) that are determined as described above. The offset prediction x21 may include, for example, DAC=−8 and DAC=4, when DAC=−28, the preset first result is 143, and when DAC=4, the preset first result is 305. Based on DAC=−28, DAC=4, and a default read voltage at the target read level, a target read voltage corresponding to DAC=−28 (denoted as x11) and a target read voltage corresponding to DAC=4 (denoted as x12) may be determined. The first result y11 is obtained by performing a read operation using the target read voltage x11, and the first result y12 is obtained by performing a read operation using the target read voltage x12. The measured point values (x11, y11) and (x12, y12) obtained by performing the read operations are input into a preset function model to obtain a valley bottom voltage. It should be noted that, referring to the preset first result (target raw FBC value) shown in column 4 in FIG. 13, the two preset first results 143 and 305 are both within the preset interval, and the two actual first results y11 and y12 are determined after performing the read operations.

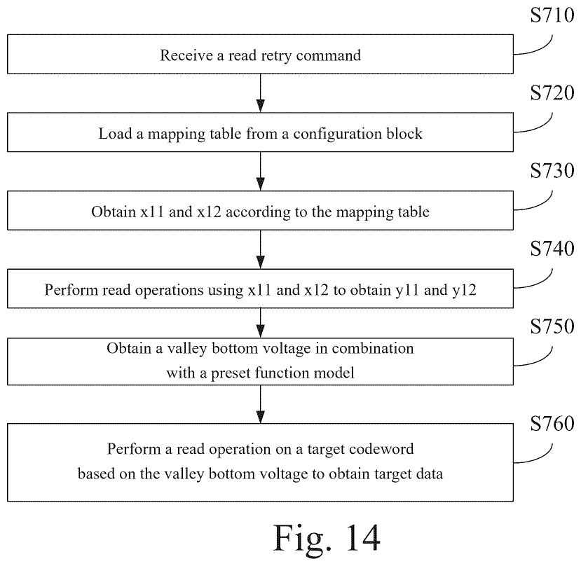

Referring to FIG. 14, FIG. 14 is a schematic flowchart of determining a valley bottom voltage according to some examples of the present disclosure. As shown in FIG. 14, at S710, receive a read retry command; at S720, load a mapping table from a configuration block; at S730, obtain x11 and x12 according to the mapping table; at S740, perform read operations using x11 and x12 to obtain y11 and y12; at S750, obtain a valley bottom voltage in combination with a preset function model; and at S760, perform a read operation on a target codeword based on the valley bottom voltage to obtain target data.

Therefore, in the first example of the present disclosure, the memory device is configured to perform two read operations, and the valley bottom voltage is calculated according to the measured point values (x11, y11) and (x12, y12). It should be noted that, when fitting using the preset function model, the selection of data is particularly important. When DAC=−28, the corresponding preset first result is 143, and when DAC=4, the corresponding preset first result is 305, wherein both the two preset first results 143 and 305 are within the preset interval. Using data within the preset interval for calculation can more accurately reflect the valley bottom voltage, which is beneficial for increasing the accuracy of the valley bottom voltage obtained through fitting using the preset model.

In a second example of the present disclosure, the at least one offset prediction includes one offset prediction; and the control logic 510 is configured to obtain the valley bottom voltage based on the one offset prediction.

With reference to FIG. 12 and FIG. 13, at least one offset prediction (for example, x21) and a preset first result is determined by looking up the mapping table based on the characteristic level (for example, the characteristic level N), the word line group (for example, the word line group A), and the target read level (for example, the target read level L7) that are determined as described above. The offset prediction x21 may include, for example, DAC=−18, and when DAC=−18, the preset first result is 45. The valley bottom voltage can be directly determined based on DAC=−18 and the default read voltage at the target read level. It should be noted that the preset first result 45 is the minimum value in the FBC, for example, the target read voltage corresponding to the preset first result is the valley bottom voltage.

Therefore, in the above second example of the present disclosure, there is no need to perform a read operation using the memory device, the valley bottom voltage is directly obtained by looking up the mapping table, and the speed of obtaining the valley bottom voltage is faster.

In a third example of the present disclosure, the at least one offset prediction includes three offset predictions, and the control logic 510 is configured to: obtain three target read voltages according to the three offset predictions; obtain a first result corresponding to the target codeword at the target read voltage; and obtain the valley bottom voltage based on the three target read voltages and the three corresponding first results in combination with a preset function model.

With reference to FIG. 12 and FIG. 13, at least one offset prediction (for example, x21) is determined by looking up the mapping table based on the characteristic level (for example, the characteristic level N), the word line group (for example, the word line group A), and the target read level (for example, the target read level L7) that are determined as described above. The offset prediction x21 may include three offset predictions, and three target read voltages, denoted as x31, x32, and x33, may be determined based on the three offset predictions. Read operations are performed respectively using the target read voltages x31, x32, and x33, to obtain first results y31, y32, and y33, and measured point values (x31, y31), (x32, y32), and (x33,y33) obtained by performing the read operations are input into a preset function model, to obtain the valley bottom voltage.

Therefore, in the third example of the present disclosure, the memory device is configured to perform three read operations, and the valley bottom voltage is calculated according to the measured point values (x31, y31), (x32, y32) and (x33, y33). It should be noted that, fitting using the measured points is beneficial for increasing the accuracy of the valley bottom voltage obtained through fitting using the preset model.

In some examples, the preset function model is related to characteristics of the memory device, and the preset function model may be obtained by fitting a large number of experimental results before the memory device leaves the factory and stored in the memory device. For example, the preset function model is encoded into code, and the code is stored in firmware or software of the memory device.

In some examples, a large amount of data is collected through a large number of experiments before the memory device leaves the factory, and analysis may be performed after preprocessing by removing outliers, sorting, denoising, and the like, and a preset function model is fitted by using a statistical method, machine learning, or another modeling technology, to describe a relationship between target read voltages and first results. For example, a regression analysis method is used to fit the preset function model using a large number of collected target read voltages and corresponding first results. For example, by using a data-driven method such as machine learning or deep learning, a preset function model is established using a large number of collected target read voltages and corresponding first results, so as to represent a relationship between the target read voltages and the first results.

In some examples, the preset function model comprises a quadratic function model comprising following function relation: y=a(x+b)²+c, wherein y represents the first result, x represents the target read voltage, b represents a prediction parameter, a represents a first parameter, and c represents a second parameter.

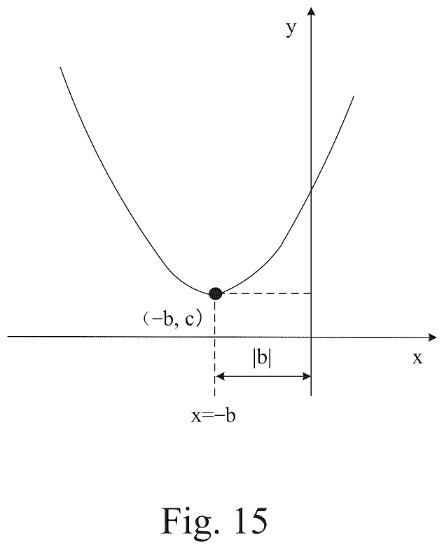

Referring to FIG. 15, FIG. 15 is a schematic diagram of a preset function model according to some examples of the present disclosure. As shown in FIG. 15, with reference to the function relation included in the above quadratic function model, it can be seen that the extremum of the quadratic function curve resides at the axis of symmetry x=−b, e.g., the position where the derivative of the quadratic function curve equals zero. For example, when the first parameter a is greater than 0, the corresponding y-value (first result) at x=−b represents the minimum value of the quadratic function curve, with the extremum point coordinates being (−b, c).

In some examples, the first parameter is a variable and the second parameter is a constant, and wherein the control logic 510 is configured to: obtain the prediction parameter based on the two target read voltages and the two corresponding first results in combination with the quadratic function model; and use the prediction parameter as the valley bottom voltage. In the above quadratic function model, if a and b are variables, then a and b can be calculated by using two measured points (x11, y11) and (x12, y12). Of course, in the above quadratic function model, if a, b and c are variables, then a, b and c can be calculated by using three measured points (x31, y31), (x32, y32) and (x33, y33). Equations 1 and 2 below illustrate a method for calculating a and b using two measured points.

$$b = \frac{{x}_{12} - {x}_{11}}{1 + \sqrt{\frac{{y}_{11} - c}{{y}_{12} - c}}} - {x}_{12} \qquad ( Equation 1 )$$

$$a = \frac{{y}_{11} - c}{{( {x}_{11} + b )}^{2}} \qquad ( Equation 2 )$$

Here, the second parameter in the function relation may be optimized using, but not limited to, a least square method, a gradient descent method, a Bayesian optimization, a Newton method, and a quasi-Newton method. The least square method is a parameter estimation method which estimates a parameter by minimizing a sum of squares for residuals between actually collected data and a prediction value of a quadratic function model. The gradient descent method takes the quadratic function model's parameters as optimization objectives, using gradient descent to find parameter values that minimize fitting errors. This involves calculating the gradient of the loss function relative to the second parameters, then updating the value of the second parameters in the opposite direction of the gradient until convergence is achieved.

In some examples, the value of the prediction parameter is an inverse of b, for example, the prediction parameter represents an abscissa corresponding to a minimum value of the quadratic function curve. The offset value between the symmetry axis (x=−b) of the quadratic function curve and the y-axis (x=0) is −b, for example, the distance between the symmetry axis of the quadratic function curve and the y-axis is the absolute value of b, |b|.

Here, x=0 may be understood as a position of a default read voltage, and the default read voltage may be a read voltage when the threshold voltage of the memory cell does not shift. It can be understood that when the offset value of the target read voltage with respect to the default read voltage (x=0) is-b, the corresponding first result at the target read voltage is the minimum value. It may be understood that using the corresponding target read voltage (equivalent to the prediction parameter) when the first result is the minimum value as the valley bottom voltage results in a low error rate and high reliability of the read result. Here, when performing a read operation on the target codeword, the value of the read voltage may be the valley bottom voltage and the reliability of the read result is high. Of course, when performing a read operation on the target codeword, the value of the read voltage is not strictly limited to the valley bottom voltage, and the valley bottom voltage may be adjusted within a certain range. When performing a read operation on the target codeword using the adjusted valley bottom voltage, the error rate of the read result may also meet the use requirement.

In some examples, the preset interval represents a numerical interval of the first results corresponding to a preset region of the preset function model's curve. The preset interval refers to a numerical interval of the first results corresponding to the test data that can accurately reflect the distribution of the actual valley bottom voltages when fitting the preset function model. In other words, the data for obtaining the valley bottom voltage is screened through the preset interval, which is beneficial to improve the accuracy of the obtained valley bottom voltage.

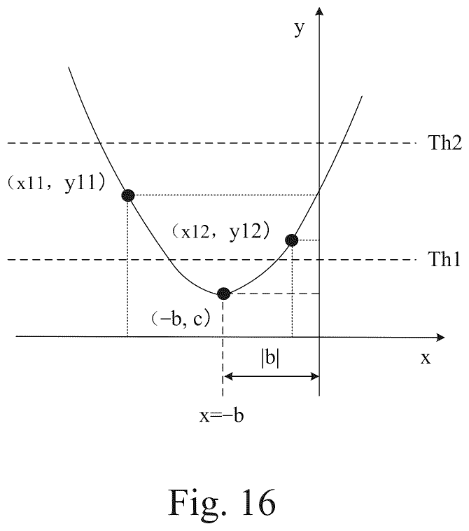

Referring to FIG. 16, FIG. 16 is a schematic diagram of determining a predicted valley bottom voltage based on a preset function model according to some examples of the present disclosure. As shown in FIG. 16, the preset interval represents a range between a first threshold and a second threshold of the quadratic function model' curve, and the first threshold (Th1) is less than the second threshold (Th2). In combination with FIG. 12, two preset first results corresponding to two offset predictions DAC=−28 and DAC=4 are both within the preset interval.

In one example, the range of the preset interval is 50 to 100. It should be noted that the range of the preset interval provided in the examples of the present disclosure is merely an example, and the range of the preset interval is related to characteristics of the memory device, and should not unduly limit the protection scope of the present disclosure.

It should be noted that, in an example of the present disclosure, at S620, the purpose of performing the read operation on the reference codeword is to obtain the first result as the characteristic value, and this read operation is performed using the reference read voltage of the reference read level, for example, the first read voltage (for example, the default read voltage of the reference level) and the second read voltage obtained by adjusting the first read voltage. In some examples, the fourth read level L4 may be used as the reference read level. At S630, the purpose of performing the read operation on the target codeword is to obtain the target data, and this read operation is performed using the valley bottom voltage of the target read level determined by looking up the mapping table. The target read level is selected from one of a plurality of read levels, and when each of the plurality of read levels is used as the target read level, a corresponding valley bottom voltage may be obtained. In some examples, if the target read level determined by looking up the mapping table is the fifth read level L5, the finally determined valley bottom voltage corresponds to the fifth read level L5, and if the target read level determined by looking up the mapping table is the third read level L3, the finally determined valley bottom voltage corresponds to the third read level L3.

In the memory device according to an example of the present disclosure, the peripheral circuit is configured to: receive a read retry command; obtain a valley bottom voltage in response to the read retry command; and perform a read operation on the target codeword based on the valley bottom voltage to obtain the target data. In a first aspect, the process of finding the valley bottom voltage is done entirely autonomously by the memory device without relying on any input or determination provided by the controller, for example, the whole process completely converges inside the memory device. This provides the memory device with novel functionalities and features, enhancing product competitiveness. In a second aspect, in this technical solution, the time required for finding the valley bottom voltage is very short, requiring only two or even one point per read level. The time for finding the valley bottom voltage can be determined based on different prediction modes—for example, two read operations are required in the first example of the present disclosure, no read operations are needed in the second example of the present disclosure, and three read operations are required in the third example of the present disclosure. In a third aspect, this technical solution achieves high positional accuracy for the valley bottom voltage and ensures high-quality autonomous error correction capability—for instance, the difference between the FBC corresponding to the valley bottom voltage and the minimum FBC is within 50. In a fourth aspect, the computational logic of this technical solution is simple, allowing different products to reuse the same algorithm with only updates to the mapping table. In a fifth aspect, leveraging the offset rule of voltage curves, characteristic values (or characteristic levels) are used to describe the offset degree of threshold voltage, thereby determining the valley bottom voltage. This enables valley bottom voltage prediction within an extremely limited selection range, reducing the probability of invalid selections to zero. Consequently, data recovery can be rapidly completed, improving the efficiency of obtaining the valley bottom voltage and preventing performance degradation of the memory device during data recovery. In a sixth aspect, the above method for obtaining the valley bottom voltage is applicable to MLC, TLC, or QLC-type memory devices.

In a second aspect, an example of the present disclosure provides a memory system, wherein the memory system 102 includes: at least one memory device 104 in the foregoing technical solutions; and a controller 106 coupled to the memory device 104 and configured to control the memory device 104.

In some examples, the controller 106 is configured to send a read retry command; the memory device 104 is configured to receive the read retry command to obtain target data; and the controller 106 is further configured to obtain the target data.

In the memory system according to an example of the present disclosure, the controller 106 sends a read retry command; the memory device 104 receives the read retry command to obtain a valley bottom voltage, and obtains target data based on the valley bottom voltage; and the controller 106 obtains the target data. The process of finding the valley bottom voltage is done entirely autonomously by the memory device 104 without relying on any input or determination provided by the controller 106, for example, the whole process completely converges inside the memory device 104.

In a third aspect, an example of the present disclosure provides an operating method of a memory device, referring back to FIG. 1 and FIG. 4, the memory device 104 includes: a memory cell array 110 including a plurality of memory cells 304, wherein a preset number of memory cells 304 among the plurality of memory cells 304 form a codeword; and a peripheral circuit 112 coupled to the memory cell array 110. Referring to FIG. 7, the operating method includes:

At S610: receiving a read retry command for instructing to obtain target data stored in a target codeword.

At S620: obtaining a valley bottom voltage in response to the read retry command, wherein the valley bottom voltage is used as a read voltage when performing a read operation on the target codeword.

At S630: performing the read operation on the target codeword based on the valley bottom voltage to obtain the target data.

In some examples, the peripheral circuit 112 includes a register 512 for storing a mapping table, and wherein the operation S620 includes: obtaining the valley bottom voltage based on the target codeword and the mapping table.

In some examples, the memory cell array 110 includes a configuration block configured to store the mapping table, and wherein the operating method further includes: storing the mapping table in the configuration block into the register 512 when the memory device 104 undergoes Power On Reset (POR).

In some examples, the number of bits stored in each of the memory cells is M, the stored M bits correspond to 2^{M}−1 read levels comprising a reference read level, and M is an integer greater than or equal to 2, and wherein before the operation S620, the operation method further comprises: obtaining a first result corresponding to a reference codeword at a reference read voltage of the reference read level as a characteristic value, wherein the first result is to indicate the number of bits flipped between two read results of the reference codeword at a first read voltage and a second read voltage, and a difference value between the first read voltage and the second read voltage is less than a preset voltage; and obtaining a characteristic level corresponding to the characteristic value based on the characteristic value, wherein the characteristic level is to indicate one or more continuously arranged characteristic values.

In some examples, before the operation S620, the operating method further includes: determining a word line group corresponding to the target codeword based on a position of the target codeword in the memory cell array, wherein the word line group is to indicate one or more word lines disposed adjacently.

In some examples, the operation S620 includes: determining at least one offset prediction based on the characteristic level, a target read level of the target codeword, and the word line group corresponding to the target codeword in combination with the mapping table, wherein the mapping table comprises a mapping relationship among the characteristic level, the target read level, the word line group, and the offset prediction; and obtaining the valley bottom voltage based on the at least one offset prediction.

In some examples, the at least one offset prediction comprises two offset predictions, and two preset first results corresponding to the two preset offsets are both within a preset interval, and wherein obtaining the valley bottom voltage based on the at least one offset prediction comprises: determining two target read voltages based on the two offset predictions; obtaining a first result corresponding to the target codeword at one of the target read voltages, and obtaining a first result corresponding to the target codeword at the other one of the target read voltages; and obtaining the valley bottom voltage based on the two target read voltages and two corresponding first results in combination with a preset function model.

In some examples, the preset function model comprises a quadratic function model comprising following function relation: y=a(x+b)²+c, wherein y represents the first result, x represents the target read voltage, b represents a prediction parameter, a represents a first parameter, and c represents a second parameter.

In some examples, obtaining the valley bottom voltage based on the two target read voltages and the two corresponding first results in combination with the preset function model comprises: obtaining the prediction parameter based on the two target read voltages and the two corresponding first results in combination with the quadratic function model; and using the prediction parameter as the valley bottom voltage.

In some examples, obtaining the first result corresponding to the reference codeword at the reference read voltage of the reference read level comprises: reading data stored in the reference codeword at the first read voltage to obtain a second result; reading data stored in the reference codeword at the second read voltage to obtain a third result; performing a logical operation on the second result and the third result to obtain a fourth result; and counting the number of bits in the fourth result indicating that the third result is flipped relative to the second result, to obtain the first result.

An example of the present disclosure further provides a storage medium having executable instructions stored thereon, which when executed, can implement the operations of the operation method in the above examples of the present disclosure.

In some examples, the storage medium may comprise a memory such as a ferromagnetic random access memory (FRAM), a ROM, a programmable read-only memory (PROM), an erasable programmable read-only memory (EPROM), an electrically erasable programmable read-only memory (EEPROM), a flash memory, a magnetic surface memory, a disc, or a compact disc read-only memory (CD-ROM); or may comprise various devices including one or any combination of the foregoing memory devices.

In some examples, executable instructions may be in the form of a program, software, software module, script, or code, written in any form of programming language (including compiled or interpreted languages, or declarative or procedural languages), and may be deployed in any form, including being deployed as a stand-alone program or as a module, component, subroutine, or other means suitable for use in a computing environment.

As an example, executable instructions may, but not necessarily, correspond to a file in a file system, may be stored in a portion of a file holding other programs or data, e.g., in one or more scripts in a hypertext markup language (HTML) document, in a single file dedicated to the program in question, or in multiple collaborative files (e.g., files storing one or more modules, subprograms, or code portions).

It should be understood that “one example” or “an example” referred to throughout the specification means that a particular feature, structure, or characteristic related to the example is included in at least one example of the present disclosure. Thus, “in one example” or “in an example” appearing throughout this specification does not necessarily refer to the same example. Furthermore, these particular features, structures, or characteristics may be combined in any suitable manner in one or more examples. It should be understood that, in the various examples of the present disclosure, the magnitude of the sequence numbers of the above processes does not imply the order of execution. The order of execution of each process should be determined by its function and internal logic, and should not constitute any limitation on the implementation process of the examples of the present disclosure. The above sequence numbers of the examples of the present disclosure are only for description and do not represent the advantages or disadvantages of the examples.

The above description constitutes only examples of the present disclosure and should not be construed as limiting the patent scope of the disclosure. Any equivalent structural modifications made under the inventive concept of the present disclosure using the content of this specification and accompanying drawings, or direct/indirect applications in other related technical fields, shall fall within the scope of patent protection of the present disclosure.

What is claimed is:

1. A memory device, comprising:
a memory cell array comprising memory cells, wherein a preset number of memory cells among the memory cells form a codeword; and
a peripheral circuit coupled to the memory cell array and configured to:
receive a read retry command for instructing to obtain target data stored in a target codeword;
obtain a valley bottom voltage in response to the read retry command, wherein the valley bottom voltage is used as a read voltage when performing a read operation on the target codeword; and
perform the read operation on the target codeword based on the valley bottom voltage to obtain the target data.

2. The memory device of claim 1, wherein the peripheral circuit comprises:
a register configured to:
store a mapping table; and
control logic coupled to the register and configured to:
receive the read retry command;
obtain the valley bottom voltage based on the target codeword and the mapping table; and
perform the read operation on the target codeword based on the valley bottom voltage to obtain the target data.

3. The memory device of claim 2, wherein the memory cell array comprises:
a configuration block configured to:
store the mapping table, and wherein
the control logic is configured to:
store the mapping table in the configuration block into the register when the memory device undergoes Power On Reset (POR).

4. The memory device of claim 2, wherein the peripheral circuit further comprises:
a latch coupled to the control logic, and wherein:
the control logic is configured to:
store the target data into the latch.

5. The memory device of claim 2, wherein a number of bits stored in each of the memory cells is M, the stored M bits correspond to 2^{M}−1 read levels comprising a reference read level, and M is an integer greater than or equal to 2, and wherein:
the control logic is configured to:
obtain a first result corresponding to a reference codeword at a reference read voltage of the reference read level as a characteristic value, wherein the first result is to indicate the number of bits flipped between two read results of the reference codeword at a first read voltage and a second read voltage, and a difference value between the first read voltage and the second read voltage is less than a preset voltage; and
obtain a characteristic level corresponding to the characteristic value based on the characteristic value, wherein the characteristic level is to indicate one or more continuously arranged characteristic values.

6. The memory device of claim 5, wherein the control logic is configured to:
determine a word line group corresponding to the target codeword based on a position of the target codeword in the memory cell array, wherein the word line group is to indicate one or more word lines disposed adjacently.

7. The memory device of claim 6, wherein the control logic is configured to:
determine at least one offset prediction based on the characteristic level, a target read level of the target codeword, and the word line group corresponding to the target codeword in combination with the mapping table, wherein the mapping table comprises a mapping relationship among the characteristic level, the target read level, the word line group, and the offset prediction; and
obtain the valley bottom voltage based on the at least one offset prediction.

8. The memory device of claim 7, wherein the at least one offset prediction comprises two offset predictions, and two preset first results corresponding to the two offset predictions are both within a preset interval, and wherein:
the control logic is configured to:
determine two target read voltages based on the two offset predictions;
obtain a first result corresponding to the target codeword at one of the target read voltages, and obtain a first result corresponding to the target codeword at the other one of the target read voltages; and
obtain the valley bottom voltage based on the two target read voltages and two corresponding first results in combination with a preset function model.

9. The memory device of claim 8, wherein the preset function model comprises a quadratic function model comprising following function relation:
y=a(x+b)²+c, wherein y represents the first result, x represents the target read voltage, b represents a prediction parameter, a represents a first parameter, and c represents a second parameter; wherein the first parameter is a variable and the second parameter is a constant, and wherein:
the control logic is configured to:
obtain the prediction parameter based on the two target read voltages and the two corresponding first results in combination with the quadratic function model; and
use the prediction parameter as the valley bottom voltage.

10. The memory device of claim 5, wherein the control logic is configured to:
read data stored in the reference codeword at the first read voltage to obtain a second result;
read data stored in the reference codeword at the second read voltage to obtain a third result;
perform a logical operation on the second result and the third result to obtain a fourth result; and
count the number of bits in the fourth result indicating that the third result is flipped relative to the second result, to obtain the first result.

11. A memory system, comprising:
at least one memory device, wherein each memory device comprises:
a memory cell array comprising memory cells, wherein a preset number of memory cells among the memory cells form a codeword; and
a peripheral circuit coupled to the memory cell array and configured to:
receive a read retry command for instructing to obtain target data stored in a target codeword;
obtain a valley bottom voltage in response to the read retry command, wherein the valley bottom voltage is used as a read voltage when performing a read operation on the target codeword; and
perform the read operation on the target codeword based on the valley bottom voltage to obtain the target data; and
a controller coupled to the memory device and configured to control the memory device.

12. The memory system of claim 11, wherein:
the controller is configured to send a read retry command,
the memory device is configured to receive the read retry command to obtain target data, and the controller is further configured to obtain the target data.

13. An operating method for a memory device, wherein the memory device comprises: a memory cell array comprising memory cells, wherein a preset number of memory cells among the memory cells form a codeword; and a peripheral circuit coupled to the memory cell array, and wherein:
the operating method comprises:
receiving a read retry command for instructing to obtain target data stored in a target codeword;
obtaining a valley bottom voltage in response to the read retry command, wherein the valley bottom voltage is used as a read voltage when performing a read operation on the target codeword; and
performing the read operation on the target codeword based on the valley bottom voltage to obtain the target data.

14. The operating method of claim 13, wherein the peripheral circuit comprises:
a register configured to:
store a mapping table, and wherein:
obtaining the valley bottom voltage in response to the read retry command comprises:
obtaining the valley bottom voltage based on the target codeword and the mapping table.

15. The operating method of claim 14, wherein the memory cell array comprises:
a configuration block configured to:
store the mapping table, and wherein:
the operating method further comprises:
storing the mapping table in the configuration block into the register when the memory device undergoes Power On Reset (POR).

16. The operating method of claim 14, wherein a number of bits stored in each of the memory cells is M, the stored M bits correspond to 2^{M}−1 read levels comprising a reference read level, and M is an integer greater than or equal to 2, and wherein:
obtaining the valley bottom voltage based on the target codeword and the mapping table comprises:
obtaining a first result corresponding to a reference codeword at a reference read voltage of the reference read level as a characteristic value, wherein the first result is to indicate the number of bits flipped between two read results of the reference codeword at a first read voltage and a second read voltage, and a difference value between the first read voltage and the second read voltage is less than a preset voltage; and
obtaining a characteristic level corresponding to the characteristic value based on the characteristic value, wherein the characteristic level is to indicate one or more continuously arranged characteristic values.

17. The operating method of claim 16, wherein obtaining the valley bottom voltage based on the target codeword and the mapping table further comprises:
determining a word line group corresponding to the target codeword based on a position of the target codeword in the memory cell array, wherein the word line group is to indicate one or more word lines disposed adjacently; and
determining at least one offset prediction based on the characteristic level, a target read level of the target codeword, and the word line group corresponding to the target codeword in combination with the mapping table, wherein the mapping table comprises a mapping relationship among the characteristic level, the target read level, the word line group, and the offset prediction; and
obtaining the valley bottom voltage based on the at least one offset prediction.

18. The operating method of claim 17, wherein the at least one offset prediction comprises two offset predictions, and two preset first results corresponding to the two offset predictions are both within a preset interval, and wherein:
obtaining the valley bottom voltage based on the at least one offset prediction comprises:
determining two target read voltages based on the two offset predictions;
obtaining a first result corresponding to the target codeword at one of the target read voltages, and obtaining a first result corresponding to the target codeword at the other one of the target read voltages; and
obtaining the valley bottom voltage based on the two target read voltages and two corresponding first results in combination with a preset function model;
wherein the preset function model comprises a quadratic function model comprising following function relation:
y=a(x+b)²+c, wherein y represents the first result, x represents the target read voltage, b represents a prediction parameter, a represents a first parameter, and c represents a second parameter.

19. The operating method of claim 18, wherein obtaining the valley bottom voltage based on the two target read voltages and the two corresponding first results in combination with the preset function model comprises:
obtaining the prediction parameter based on the two target read voltages and the two corresponding first results in combination with the quadratic function model; and
using the prediction parameter as the valley bottom voltage.

20. The operating method of claim 16, wherein obtaining the first result corresponding to the reference codeword at the reference read voltage of the reference read level comprises:
reading data stored in the reference codeword at the first read voltage to obtain a second result;
reading data stored in the reference codeword at the second read voltage to obtain a third result;
performing a logical operation on the second result and the third result to obtain a fourth result; and
counting the number of bits in the fourth result indicating that the third result is flipped relative to the second result, to obtain the first result.
